(19) United States
(12) Patent Application Publication
(10) Pub. No.: US 2026/0104731 A1
(43) Pub. Date: Apr. 16, 2026

(54) FOLDING SET AND ELECTRONIC DEVICE INCLUDING THE SAME

(71) Applicant: Samsung Display Co., Ltd., Yongin-si (KR)

(72) Inventors: IN SOO PARK, Yongin-si (KR); SANGHYO PARK, Yongin-si (KR)

(21) Appl. No.: 19/307,697

(22) Filed: Aug. 22, 2025

(30) Foreign Application Priority Data
Oct. 16, 2024 (KR) 10-2024-0141461

(51) Int. Cl. G06F 1/16; H10K 59/123; H10K 59/131

(52) U.S. Cl. CPC G06F 1/1616; G06F 1/1681; H10K 59/123; H10K 59/131

(57) ABSTRACT

A folding set includes: a first folding set including a first frame, a second frame, and a hinge between the first frame and the second frame; and a second folding set including a first body under the first frame and a second body under the second frame. The first frame and the hinge are coupled with each other to define a first frame shape having a first opening defined therein, and the second frame and the hinge are coupled with each other to define a second frame shape having a second opening defined therein. The first body is exposed by the first opening, and the second body is exposed by the second opening.

### CROSS-REFERENCE TO RELATED APPLICATION

The present application claims priority to and the benefit of Korean Patent Application No. 10-2024-0141461, filed on Oct. 16, 2024, in the Korean Intellectual Property Office, the entire disclosure of which is incorporated herein by reference.

### BACKGROUND

### 1. Field

Aspects of embodiments of the present disclosure relate to a folding set and an electronic device including the same.

### 2. Description of the Related Art

Electronic devices, such as a smart phone, a digital camera, a notebook computer, a car navigation device, and a smart television, which provide (e.g., emit or display) an image to a user include a display device for displaying the image. The display device generates an image and provides the image to the user through a display screen.

With the development of display device technology, various types of display devices are being developed. For example, various flexible display devices that can be being curved, folded, or rolled are being developed. The flexible display devices that may be deformed in various ways are easy to carry and improve user convenience.

From among the flexible display devices, a foldable display device may be folded about a folding axis extending in one direction. The foldable display device may be folded by a mechanism, such as a folding set.

### SUMMARY

Embodiments of the present disclosure provide a folding set that reduces deformation of a display device by easily fixing and folding the display device and an electronic device including the folding set.

According to an embodiment of the present disclosure, a folding set: includes a first folding set including a first frame, a second frame, and a hinge between the first frame and the second frame; and a second folding set including a first body under the first frame and a second body under the second frame. The first frame and the hinge are coupled with each other to define a first frame shape having a first opening defined therein, and the second frame and the hinge are coupled with each other to define a second frame shape having a second opening defined therein. The first body is exposed by the first opening, and the second body is exposed by the second opening.

According to an embodiment of the present disclosure, a folding set includes: a first folding set including a first frame, a second frame, and a hinge between the first frame and the second frame; and a second folding set including a first body under the first frame and a second body under the second frame. The first frame and the hinge are coupled with each other to define a first frame shape having a first opening defined therein, and the second frame and the hinge are coupled with each other to define a second frame shape having a second opening defined therein. Each of an upper portion of an inner surface of the first frame that defines the first opening and an upper portion of an inner surface of the second frame that defines the second opening has a step portion having a stepped shape.

According to an embodiment of the present disclosure, an electronic device includes: a first folding set that includes a first frame, a second frame, and a hinge between the first frame and the second frame and has openings defined between the hinge, the first frame, and the second frame; a second folding set including a first body under the first frame and a second body under the second frame; and a display device on the second folding set through the openings. Each of an upper portion of an inner surface of the first frame and an upper portion of an inner surface of the second frame that define the openings has a step portion having a stepped shape, and the display device is on the first body, the second body, and the step portion.

### BRIEF DESCRIPTION OF THE DRAWINGS

The above and other aspects and features of the present disclosure will become apparent by describing, in detail, embodiments thereof with reference to the accompanying drawings, in which:

FIG. 1 is a perspective view of a display device coupled to a folding set according to an embodiment of the present disclosure.

FIG. 2 is a view illustrating the display device illustrated in FIG. 1 in a folded state.

FIG. 3 is a view illustrating a cross-section of an electronic panel of the display device illustrated in FIG. 1.

FIG. 4 is a view illustrating a cross-section of a display panel illustrated in FIG. 3.

FIG. 5 is a plan view of the display panel illustrated in FIG. 3.

FIG. 6 is a view illustrating a cross-section of the electronic panel corresponding to any one pixel illustrated in FIG. 5.

FIG. 7 is a sectional view taken along the line I-I′ in FIG. 5.

FIG. 8 is a view illustrating a state in which a bending area illustrated in FIG. 7 is bent.

FIG. 9 is a view illustrating a folded state of the display device illustrated in FIG. 7.

FIG. 10 is a perspective view of an electronic device including the folding set according to an embodiment of the present disclosure.

FIG. 11 is an exploded perspective view of the electronic device illustrated in FIG. 10.

FIG. 12 is an exploded perspective view illustrating a front side of the folding set illustrated in FIG. 11.

FIG. 13 is an exploded perspective view illustrating a rear side of the folding set illustrated in FIG. 11.

FIG. 14 is an exploded perspective view illustrating a front side of a first folding set illustrated in FIG. 12.

FIG. 15 is an exploded perspective view illustrating a rear side of the first folding set illustrated in FIG. 13.

FIG. 16 is an exploded perspective view illustrating a front side of a second folding set illustrated in FIG. 12.

FIG. 17 is an exploded perspective view illustrating a rear side of the second folding set illustrated in FIG. 13.

FIG. 18 is an enlarged view illustrating a portion of the folding set illustrated in FIG. 11 at where a pair of first rotating parts and a pair of second rotating parts are disposed adjacent to each other.

FIG. 19 is a side view of the first rotating parts and the second rotating parts as viewed in a second direction.

FIG. 20 is a view illustrating of the folding set illustrated in FIG. 11 in an unfolded state.

FIG. 21 is a view illustrating the folding set illustrated in FIG. 11 in a folded state.

FIG. 22 is a sectional view taken along the line II-II′ in FIG. 10.

FIG. 23 is an enlarged view of the first area A1 in FIG. 22.

FIG. 24 is a view illustrating the folding set illustrated in FIG. 22 in a folded state.

FIG. 25 is a sectional view taken along the line III-III′ in FIG. 10.

FIG. 26 is a view illustrating the folding set and the display device illustrated in FIG. 25 in a folded state.

FIG. 27 is a sectional view taken along the line IV-IV′ in FIG. 10.

FIG. 28A is a side view of the display device when the display device illustrated in FIG. 1 is viewed in the second direction.

FIG. 28B is a view illustrating the display device illustrated in FIG. 28A in a folded state.

FIG. 29 is a view illustrating a deformed state of the display device when the display device illustrated in FIG. 27 is folded.

FIG. 30 is a view illustrating a configuration of a folding set according to a comparative example.

FIG. 31 is a view illustrating a deformed state of the display device when the comparative folding set illustrated in FIG. 30 is folded.

FIG. 32 is a view illustrating a configuration of second rotating parts according to an embodiment of the present disclosure.

FIGS. 33A and 33B are views illustrating a configuration of a folding set according to an embodiment of the present disclosure.

### DETAILED DESCRIPTION

It will be understood that when an element or layer is referred to as being “on,” “connected to,” or “coupled to” another element or layer, it may be directly on, connected, or coupled to the other element or layer or one or more intervening elements or layers may also be present. When an element or layer is referred to as being “directly on,” “directly connected to,” or “directly coupled to” another element or layer, there are no intervening elements or layers present. For example, when a first element is described as being “coupled” or “connected” to a second element, the first element may be directly coupled or connected to the second element or the first element may be indirectly coupled or connected to the second element via one or more intervening elements.

In the figures, dimensions of the various elements, layers, etc. may be exaggerated for clarity of illustration. The same reference numerals designate the same elements. As used herein, the term “and/or” includes any and all combinations of one or more of the associated listed items. Further, the use of “may” when describing embodiments of the present disclosure relates to “one or more embodiments of the present disclosure.” Expressions, such as “at least one of” and “any one of,” when preceding a list of elements, modify the entire list of elements and do not modify the individual elements of the list. For example, the expression “at least one of a, b, or c” indicates only a, only b, only c, both a and b, both a and c, both b and c, all of a, b, and c, or variations thereof. As used herein, the terms “use,” “using,” and “used” may be considered synonymous with the terms “utilize,” “utilizing,” and “utilized,” respectively. As used herein, the terms “substantially,” “about,” and similar terms are used as terms of approximation and not as terms of degree, and are intended to account for the inherent variations in measured or calculated values that would be recognized by those of ordinary skill in the art.

It will be understood that, although the terms first, second, third, etc. may be used herein to describe various elements, components, regions, layers, and/or sections, these elements, components, regions, layers, and/or sections should not be limited by these terms. These terms are used to distinguish one element, component, region, layer, or section from another element, component, region, layer, or section.

Thus, a first element, component, region, layer, or section discussed below could be termed a second element, component, region, layer, or section without departing from the teachings of example embodiments.

Spatially relative terms, such as “beneath,” “below,” “lower,” “above,” “upper,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” or “over” the other elements or features. Thus, the term “below” may encompass both an orientation of above and below. The device may be otherwise oriented (rotated 90 degrees or at other orientations), and the spatially relative descriptors used herein should be interpreted accordingly.

The terminology used herein is for the purpose of describing embodiments of the present disclosure and is not intended to be limiting of the present disclosure. As used herein, the singular forms “a” and “an” are intended to include the plural forms as well, unless the context clearly indicates otherwise. It will be further understood that the terms “includes,” “including,” “comprises,” and/or “comprising,” when used in this specification, specify the presence of stated features, integers, steps, operations, elements, and/or components but do not preclude the presence or addition of one or more other features, integers, steps, operations, elements, components, and/or groups thereof.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

Also, any numerical range disclosed and/or recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein, and any minimum numerical limitation recited in this specification is intended to include all higher numerical limitations subsumed therein.

Accordingly, Applicant reserves the right to amend this specification, including the claims, to expressly recite any sub-range subsumed within the ranges expressly recited herein. All such ranges are intended to be inherently described in this specification such that amending to expressly recite any such subranges would comply with the requirements of 35 U.S.C. § 112(a) and 35 U.S.C. § 132(a).

Unless otherwise defined, all terms used herein, including technical or scientific terms, have the same meanings as those generally understood by those skilled in the art to which the present disclosure pertains. Such terms as those defined in a generally used dictionary are to be interpreted as having meanings consistent with the contextual meanings in the relevant field of art and should not to be interpreted as having an ideal or excessively formal meaning unless clearly defined as having such in the present application.

Hereinafter, embodiments of the present disclosure will be described with reference to the accompanying drawings.

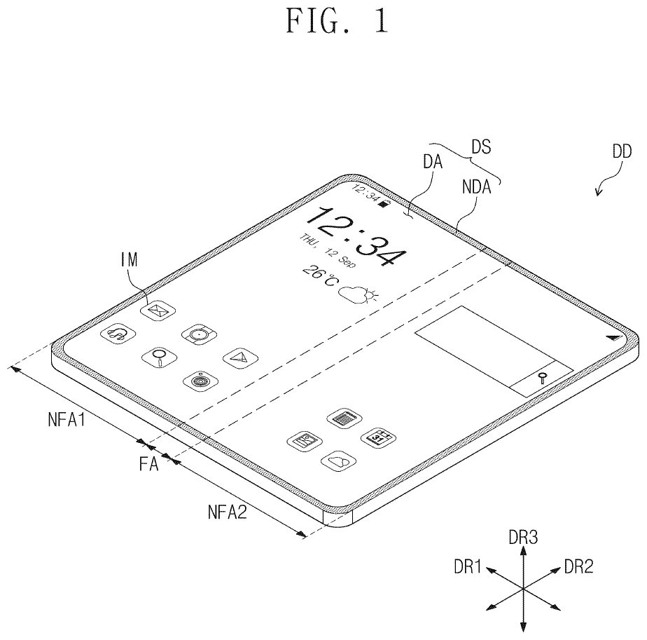

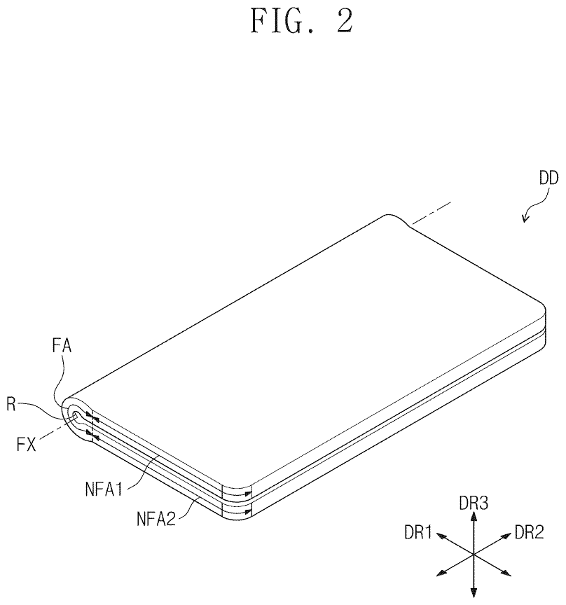

FIG. 1 is a perspective view of a display device coupled to a folding set according to an embodiment of the present disclosure. FIG. 2 is a view illustrating the display device illustrated in FIG. 1 in a folded state.

Referring to FIG. 1, the display device DD, according to an embodiment of the present disclosure, may have short sides extending in a first direction DR1 and long sides extending in a second direction DR2 crossing the first direction DR1. The display device DD may have a rounded rectangular shape with rounded corners. The display device DD may be a flexible display device.

Hereinafter, a direction substantially perpendicular to a plane defined by the first direction DR1 and the second direction DR2 is defined as a third direction DR3.

The expression “when viewed from above the plane” as used herein may mean that an object is viewed in the third direction DR3. The term “overlap” as used herein may be defined as being when portions of components overlap each other when viewed from above the plane.

The display device DD may have a folding area FA and a plurality of non-folding areas NFA1 and NFA2. The non-folding areas NFA1 and NFA2 may include the first non-folding area NFA1 and the second non-folding area NFA2. The folding area FA may be disposed between the first non-folding area NFA1 and the second non-folding area NFA2. The first non-folding area NFA1, the folding area FA, and the second non-folding area NFA2 may be arranged in the first direction DR1.

Although an embodiment in which the display device DD has one folding area FA and two non-folding areas NFA1 and NFA2 is illustrated as an example, the number of folding areas FA and the number of non-folding areas NFA1 and NFA2 are not limited thereto. For example, the display device DD may include more than two non-folding areas and a plurality of folding areas disposed between the non-folding areas.

The upper surface of the display device DD may be defined as a display surface DS, and the display surface DS may have (or may form) a plane defined by the first direction DR1 and the second direction DR2. Images IM generated by the display device DD may be provided to a user through the display surface DS.

The display surface DS may have a display area DA and a non-display area NDA around (e.g., extending around a periphery of) the display area DA. The display area DA may display an image, and the non-display area NDA may not display an image. The non-display area NDA may define the border of the display device DD that surrounds the display area DA and may be printed in a color (e.g., a predetermined color).

The display device DD may further include at least one sensor and at least one camera.

Referring to FIG. 2, the display device DD may be a foldable display device DD. For example, the folding area FA may be bent about a folding axis FX parallel to the second direction DR2, and the display device DD may be folded accordingly. The folding axis FX may be defined as a long axis parallel to the long sides of the display device DD. However, without being limited thereto, the folding axis FX may be defined as a short axis parallel to the short sides of the display device DD, and the display device DD may be folded about the folding axis parallel to the short sides.

When the display device DD is folded, the first non-folding area NFA1 and the second non-folding area NFA2 may face each other, and the display device DD may be folded in an in-folding manner such that the display surface DS is not exposed to the outside. However, embodiments of the present disclosure are not limited thereto. For example, the display device DD may be folded about the folding axis FX in an out-folding manner such that the display surface DS is exposed to the outside.

The distance between the first non-folding area NFA1 and the second non-folding area NFA2 may be smaller than the diameter of the circle defined by the radius of curvature R of the folding area FA. In this case, the folding area FA may be folded in a dumbbell shape, and the first non-folding area NFA1 and the second non-folding area NFA2 may be closer to (e.g., may contact) each other.

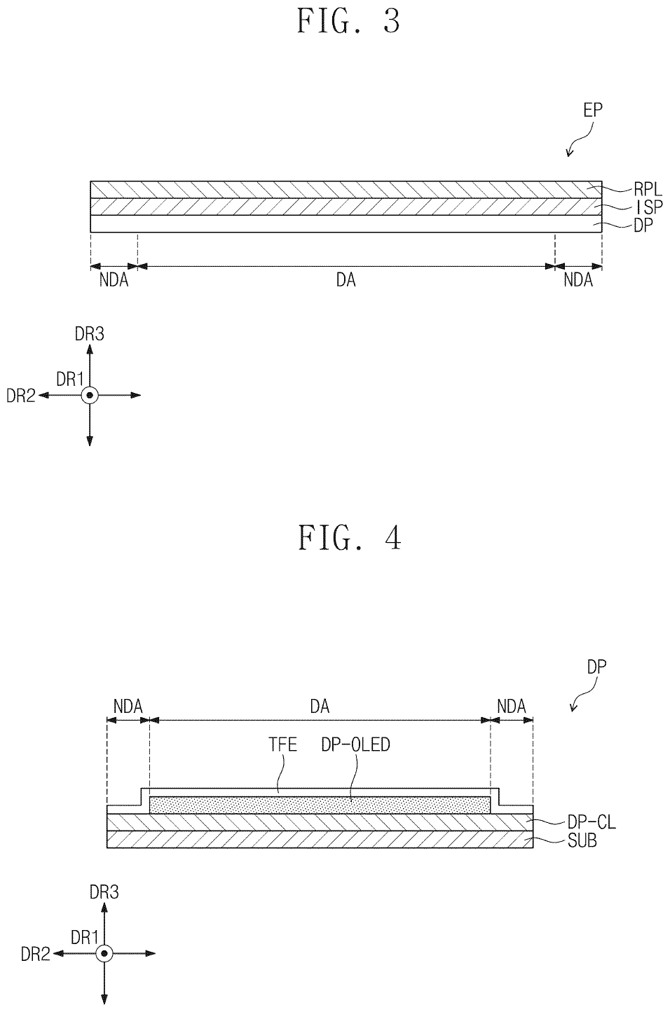

FIG. 3 is a view illustrating a cross-section of an electronic panel of the display device illustrated in FIG. 1. FIG. 4 is a view illustrating a cross-section of a display panel illustrated in FIG. 3.

For example, FIGS. 3 and 4 illustrate cross-sections viewed in the first direction DR1.

Referring to FIG. 3, the electronic panel EP may include the display panel DP, an input sensing part ISP disposed on the display panel DP, and an anti-reflective layer RPL disposed on the input sensing part ISP.

The display panel DP may be a flexible display panel. The display panel DP, according to an embodiment of the present disclosure, may be an emissive display panel but is not particularly limited. For example, the display panel DP may be an organic light emitting display panel or an inorganic light emitting display panel. An emissive layer of the organic light emitting display panel may include an organic luminescent material. An emissive layer of the inorganic light emitting display panel may include a quantum dot and a quantum rod. Hereinafter, the display panel DP will be described as an organic light emitting display panel as an example.

The input sensing part ISP may include a plurality of sensing parts for sensing an external input in a capacitance type. The input sensing part ISP may be directly manufactured on (or directly formed on) the display panel DP when the display device DD is manufactured. However, without being limited thereto, the input sensing part ISP may be manufactured as a panel separate from the display panel DP and may be attached to the display panel DP by an adhesive layer.

The anti-reflective layer RPL may be directly manufactured on (or directly formed on) the input sensing part ISP when the display device DD is manufactured.

However, without being limited thereto, the anti-reflective layer RPL may be manufactured as a separate panel and may be attached to the input sensing part ISP by an adhesive layer.

The anti-reflective layer RPL may be defined as a film for preventing reflection of external light. The anti-reflective layer RPL may decrease the reflectance of external light incident on the display panel DP from above the display device DD.

Referring to FIG. 4, the display panel DP may include a substrate SUB, a circuit element layer DP-CL disposed on the substrate SUB, a display element layer DP-OLED disposed on the circuit element layer DP-CL, and a thin film encapsulation layer TFE disposed on the display element layer DP-OLED.

The substrate SUB may have a display area DA and a non-display area NDA around the display area DA. The substrate SUB may include a flexible plastic material, such as glass or polyimide (PI). The display element layer DP-OLED may be disposed in the display area DA.

A plurality of pixels may be disposed in the circuit element layer DP-CL and the display element layer DP-OLED. Each of the pixels may include a transistor disposed in the circuit element layer DP-CL and a light emitting element disposed in the display element layer DP-OLED and connected to the transistor.

The thin film encapsulation layer TFE may be disposed on the circuit element layer DP-CL to cover the display element layer DP-OLED. The thin film encapsulation layer TFE may protect the pixels from moisture, oxygen, and external foreign matter.

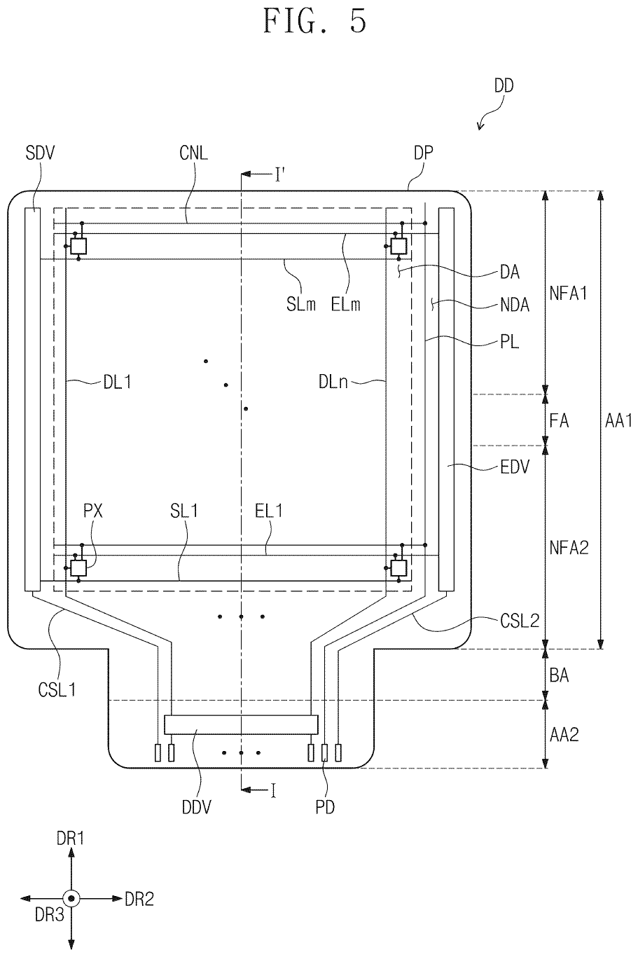

FIG. 5 is a plan view of the display panel illustrated in FIG. 3.

Referring to FIG. 5, the display device DD may include the display panel DP, a scan driver SDV, a data driver DDV, and a light emission driver EDV.

The display panel DP may have a first area AA1, a second area AA2, and a bending area BA between the first area AA1 and the second area AA2. The bending area BA may extend in the second direction DR2, and the first area AA1, the bending area BA, and the second area AA2 may be arranged in the first direction DR1.

The first area AA1 may include a display area DA and a non-display area NDA around the display area DA. The non-display area NDA may surround (e.g., may extend around a periphery of) the display area DA. The display area DA may be an area at where an image is displayed, and the non-display area NDA may be an area at where no image is displayed. The second area AA2 and the bending area BA may be areas where no image is displayed.

The first area AA1 may include a first non-folding area NFA1, a second non-folding area NFA2, and a folding area FA between the first non-folding area NFA1 and the second non-folding area NFA2. The first non-folding area NFA1, the second non-folding area NFA2, and the folding area FA may correspond to the first non-folding area NFA1, the second non-folding area NFA2, and the folding area FA of the display device DD described above with reference to FIG. 1.

The first area AA1 may be bent and folded about the above-described folding axis FX. For example, the display panel DP may be folded when the folding area FA in the first area AA1 is folded about the above-described folding axis FX.

The display panel DP may include a plurality of pixels PX, a plurality of scan lines SL1 to SLm, a plurality of data lines DL1 to DLn, a plurality of light emission lines EL1 to ELm, a first control line CSL1, a second control line CSL2, a power line PL, a plurality of connecting lines CNL, and a plurality of pads PD. “m” and “n” are natural numbers. The pixels PX may be disposed in the display area DA and may be connected to the scan lines SL1 to SLm, the data lines DL1 to DLn, and the light emission lines EL1 to ELm.

The scan driver SDV and the light emission driver EDV may be disposed in the non-display area NDA. The scan driver SDV and the light emission driver EDV may be disposed in the non-display areas NDA adjacent to opposite sides of the first area AA1 opposite to each other in the second direction DR2. The data driver DDV may be disposed in the second area AA2. The data driver DDV may be manufactured in the form of an integrated circuit (IC) chip and may be mounted on the second area AA2.

The scan lines SL1 to SLm may extend in the second direction DR2 and may be connected to the scan driver SDV. The data lines DL1 to DLn may extend in the first direction DR1 and may be connected to the data driver DDV via (e.g., while passing through) the bending area BA. The data driver DDV may be connected to the pixels PX through the data lines DL1 to DLn. The light emission lines EL1 to ELm may extend in the second direction DR2 and may be connected to the light emission driver EDV.

The power line PL may extend in the first direction DR1 and may be disposed in the non-display area NDA. The power line PL may be disposed between the display area DA and the light emission driver EDV. The power line PL may extend to the second area AA2 via the bending area BA. The power line PL may extend toward the lower end of the second area AA2 when viewed from above the plane. The power line PL may receive a drive voltage.

The connecting lines CNL may extend in the second direction DR2 and may be arranged in the first direction DR1. The connecting lines CNL may be connected to the power line PL and the pixels PX. The drive voltage may be applied to the pixels PX through the power line PL and the connecting lines CNL connected with each other.

The first control line CSL1 may be connected to the scan driver SDV and may extend toward the lower end of the second area AA2 via the bending area BA.

The second control line CSL2 may be connected to the light emission driver EDV and may extend toward the lower end of the second area AA2 via the bending area BA. The data driver DDV may be disposed between the first control line CSL1 and the second control line CSL2.

The pads PD may be disposed adjacent to the lower end of the second area AA2 when viewed from above the plane. The pads PD may be arranged in the second direction DR2. The data driver DDV, the power line PL, the first control line CSL1, and the second control line CSL2 may be connected to the pads PD.

The data lines DL1 to DLn may be connected to the corresponding pads PD through the data driver DDV. For example, the data lines DL1 to DLn may be connected to the data driver DDV, and the data driver DDV may be connected to the pads PD corresponding to the data lines DL1 to DLn.

A printed circuit board (PCB) may be connected to the pads PD, and a timing controller and a voltage generator may be disposed on the printed circuit board. The timing controller may be manufactured in the form of an integrated circuit (IC) chip and may be mounted on the printed circuit board. The timing controller and the voltage generator may be connected to the pads PD through the printed circuit board.

The timing controller may control operations of the scan driver SDV, the data driver DDV, and the light emission driver EDV. The timing controller may generate a scan control signal, a data control signal, and a light emission control signal in response to control signals received from the outside (e.g., received from an external device or external source). The voltage generator may generate the drive voltage.

The scan control signal may be provided to the scan driver SDV through the first control line CSL1. The light emission control signal may be provided to the light emission driver EDV through the second control line CSL2. The data control signal may be provided to the data driver DDV. The timing controller may receive image signals from the outside, may convert the data format of the image signals according to the specification of an interface with the data driver DDV, and may provide the converted signals to the data driver DDV.

The scan driver SDV may generate a plurality of scan signals in response to the scan control signal. The scan signals may be applied to the pixels PX through the scan lines SL1 to SLm. The scan signals may be sequentially applied to the pixels PX.

The data driver DDV may generate a plurality of data voltages corresponding to the image signals in response to the data control signal. The data voltages may be applied to the pixels PX through the data lines DL1 to DLn. The light emission driver EDV may generate a plurality of light emission signals in response to the light emission control signal. The light emission signals may be applied to the pixels PX through the light emission lines EL1 to ELm.

The pixels PX may receive the data voltages in response to the scan signals. The pixels PX may display an image by emitting light having luminance corresponding to the data voltages in response to the light emission signals. The light emission time of the pixels PX may be controlled by the light emission signals.

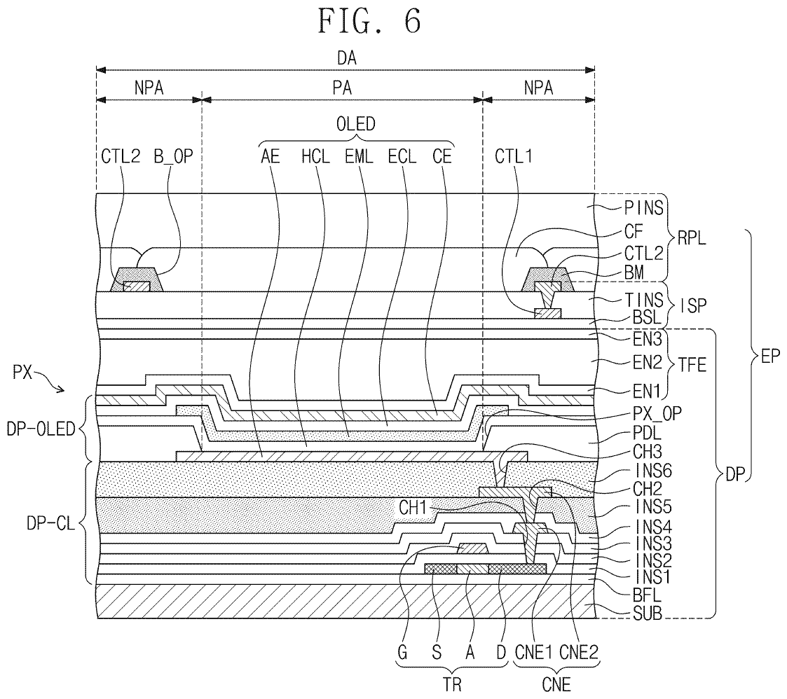

FIG. 6 is a view illustrating a cross-section of the electronic panel corresponding to any one pixel illustrated in FIG. 5.

Referring to FIG. 6, the display panel DP may include a pixel PX, and the pixel PX may include a transistor TR and a light emitting element OLED. The light emitting element OLED may include a first electrode AE (e.g., an anode), a second electrode CE (e.g., a cathode), a hole control layer HCL, an electron control layer ECL, and an emissive layer EML.

The transistor TR and the light emitting element OLED may be disposed on the substrate SUB. Although one transistor TR is illustrated as an example, the pixel PX may include a plurality of transistors and at least one capacitor for driving the light emitting element OLED.

The display area DA may have an emissive area PA corresponding to each of the pixels PX and a non-emissive area NPA around (e.g., extending around a periphery of) each of the emissive areas PA. The light emitting element OLED may be disposed in the emissive area PA.

A buffer layer BFL may be disposed on the substrate SUB. The buffer layer BFL may be an inorganic layer. A semiconductor pattern may be disposed on the buffer layer BFL. The semiconductor pattern may include poly silicon, amorphous silicon, or metal oxide.

The semiconductor pattern may be doped with an N-type dopant or a P-type dopant. The semiconductor pattern may have highly-doped areas and a lightly-doped area. The highly-doped areas may have a higher conductivity than the lightly-doped area and may act as a source electrode and a drain electrode of the transistor TR. The lightly-doped area may substantially correspond to an active (e.g., channel) area of the transistor TR.

The source S, the active area A, and the drain D of the transistor TR may be formed from the semiconductor pattern. A first insulating layer INS1 may be disposed on the semiconductor pattern. A gate G of the transistor TR may be disposed on the first insulating layer INS1. A second insulating layer INS2 may be disposed on the gate G. A third insulating layer INS3 may be disposed on the second insulating layer INS2.

A connecting electrode CNE may include a first connecting electrode CNE1 and a second connecting electrode CNE2 to connect the transistor TR and the light emitting element OLED. The first connecting electrode CNE1 may be disposed on the third insulating layer INS3 and may be connected to the drain D through a first contact hole (e.g., a first contact opening) CH1 defined in the first to third insulating layers INS1 to INS3.

A fourth insulating layer INS4 may be disposed on the first connecting electrode CNE1. A fifth insulating layer INS5 may be disposed on the fourth insulating layer INS4. The second connecting electrode CNE2 may be disposed on the fifth insulating layer INS5. The second connecting electrode CNE2 may be connected to the first connecting electrode CNE1 through a second contact hole (e.g., a second contact opening) CH2 defined in the fourth insulating layer INS4 and the fifth insulating layer INS5.

A sixth insulating layer INS6 may be disposed on the second connecting electrode CNE2. The layers from the buffer layer BFL to the sixth insulating layer INS6 may be collectively referred to as the circuit element layer DP-CL. The first to sixth insulating layers INS1 to INS6 may be inorganic layers or organic layers.

The first electrode AE may be disposed on the sixth insulating layer INS6. The first electrode AE may be connected to the second connecting electrode CNE2 through a third contact hole (e.g., a third contact opening) CH3 defined in the sixth insulating layer INS6. A pixel defining layer PDL having an opening PX_OP defined therein to expose a portion (e.g., a predefined or central portion) of the first electrode AE may be disposed on the first electrode AE and the sixth insulating layer INS6.

The hole control layer HCL may be disposed on the first electrode AE and the pixel defining layer PDL. The hole control layer HCL may include a hole transport layer and a hole injection layer.

The emissive layer EML may be disposed on the hole control layer HCL. The emissive layer EML may be disposed in an area corresponding to the opening PX_OP. The emissive layer EML may include an organic material and/or an inorganic material. The emissive layer EML may generate (e.g., may emit) one of red light, green light, and blue light.

The electron control layer ECL may be disposed on the emissive layer EML and the hole control layer HCL. The electron control layer ECL may include an electron transport layer and an electron injection layer. The hole control layer HCL and the electron control layer ECL may be commonly disposed in the emissive area PA and the non-emissive area NPA.

The second electrode CE may be disposed on the electron control layer ECL. The second electrode CE may be commonly disposed in the pixels PX. The layer in which the light emitting element OLED is disposed may be defined as the display element layer DP-OLED.

The thin film encapsulation layer TFE may be disposed on the second electrode CE and may cover the pixel PX. The thin film encapsulation layer TFE may include a first encapsulation layer EN1 disposed on the second electrode CE, a second encapsulation layer EN2 disposed on the first encapsulation layer EN1, and a third encapsulation layer EN3 disposed on the second encapsulation layer EN2.

The first encapsulation layer EN1 and the third encapsulation layer EN3 may include an inorganic insulating layer and may protect the pixel PX from moisture/oxygen. The second encapsulation layer EN2 may include an organic insulating layer and may protect the pixel PX from foreign matter, such as dust particles.

A first voltage may be applied to the first electrode AE through the transistor TR, and a second voltage having a lower level than the first voltage may be applied to the second electrode CE. Holes and electrons injected into the emissive layer EML may be combined to form excitons, and as the excitons transition to a ground state, the light emitting element OLED (e.g., the emissive layer EML) may emit light.

The layers from the substrate SUB to the thin film encapsulation layer TFE may be defined as the display panel DP. The input sensing part ISP may be disposed on the thin film encapsulation layer TFE. The input sensing part ISP may be directly manufactured on the upper surface of the thin film encapsulation layer TFE.

A base layer BSL may be disposed on the thin film encapsulation layer TFE. The base layer BSL may include an inorganic insulating layer. At least one inorganic insulating layer may be provided on the thin film encapsulation layer TFE as the base layer BSL.

The input sensing part ISP may include a first conductive pattern CTL1 and a second conductive pattern CTL2 disposed on the first conductive pattern CTL1. The first conductive pattern CTL1 may be disposed on the base layer BSL. An insulating layer TINS may be disposed on the base layer BSL to cover the first conductive pattern CTL1. The insulating layer TINS may include an inorganic insulating layer or an organic insulating layer. The second conductive pattern CTL2 may be disposed on the insulating layer TINS.

The first conductive pattern CTL1 and the second conductive pattern CTL2 may overlap the non-emissive area NPA. The first conductive pattern CTL1 and the second conductive pattern CTL2 may be disposed on the non-emissive area NPA between the emissive areas PA and may have (or may form) a mesh shape.

The first conductive pattern CTL1 and the second conductive pattern CTL2 may form sensors of the input sensing part ISP, described above. For example, the first conductive pattern CTL1 and the second conductive pattern CTL2 having a mesh shape may be separated from each other in an area to form the sensors. A portion of the second conductive pattern CTL2 may be connected to the first conductive pattern CTL1.

The anti-reflective layer RPL may be disposed on the second conductive pattern CTL2. The anti-reflective layer RPL may include a black matrix BM and a plurality of color filters CF. The black matrix BM may overlap the non-emissive area NPA, and the color filters CF may overlap the emissive areas PA, respectively.

The black matrix BM may be disposed on the insulating layer TINS to cover the second conductive pattern CTL2. An opening B_OP that overlaps the emissive area PA and the opening PX_OP may be defined in the black matrix BM. The black matrix BM may absorb and block light. The width of the opening B_OP may be greater than the width of the opening PX_OP.

The color filters CF may be disposed on the insulating layer TINS and the black matrix BM. The color filters CF may be disposed in the openings B_OP, respectively. A planarization insulating layer PINS may be disposed on the color filters CF. The planarization insulating layer PINS may provide a flat upper surface.

When external light travelling toward the display panel DP is reflected from the display panel DP and provided back to the user, the user may visually recognize the external light as a mirror effect. To prevent such a phenomenon, the anti-reflective layer RPL may include the color filters CF that display the same colors as those of the pixels PX of the display panel DP. The color filters CF may filter the external light into the same colors as those of the pixels PX. In this case, the external light may not be visible to the user.

However, embodiments of the present disclosure are not limited thereto, and the anti-reflective layer RPL may include a polarizer film to decrease the reflectance of external light. The polarizer film may be separately manufactured and may be attached to the input sensing part ISP by an adhesive layer. The polarizer film may include a phase retarder and/or a polarizer.

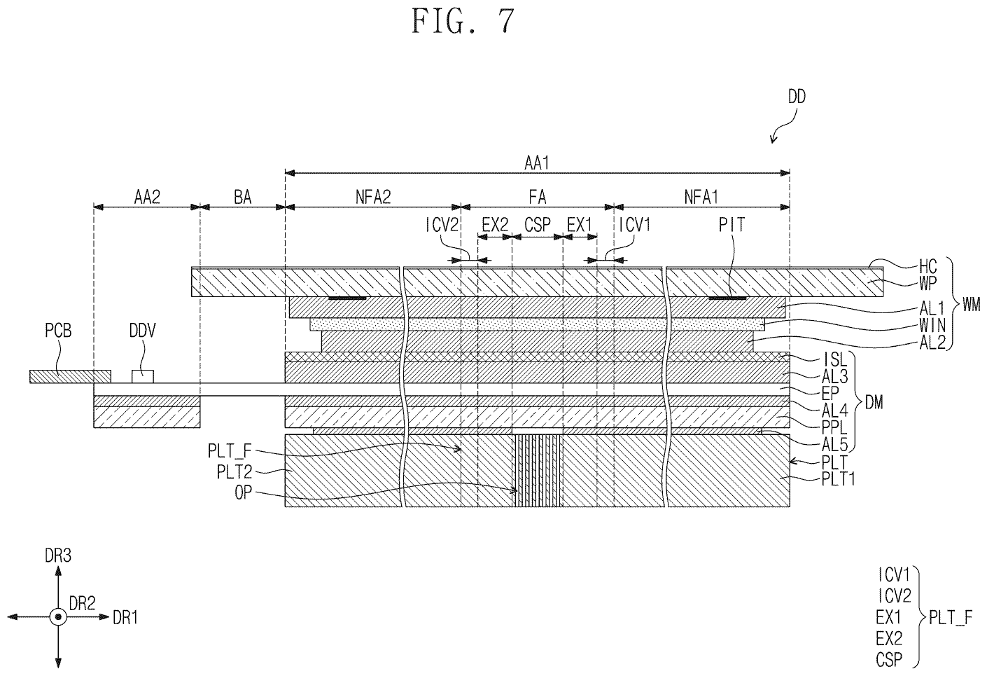

FIG. 7 is a sectional view taken along the line I-I′ in FIG. 5.

For example, a cross-section of the display panel DP corresponding to the line I-I′ and a cross-section of components disposed on and under the display panel DP are illustrated together in FIG. 7.

Referring to FIG. 7, the display device DD may include a display module DM, a window module WM, and a support part PLT. The window module WM may be disposed on the display module DM and may protect the display module DM from external scratches. The support plate PLT may be disposed under the display module DM and may support the display module DM.

The display module DM may be a flexible display module. The display module DM may have a first non-folding area NFA1, a folding area FA, and a second non-folding area NFA2. As the folding area FA is folded about the above-described folding axis FX, the display module DM may be folded.

The window module WM may include a hard coating layer HC, a printed layer PIT, a window WIN, a window protection layer WP, a first adhesive layer AL1, and a second adhesive layer AL2. The display module DM may include an impact absorbing layer ISL, the electronic panel EP, a panel protection layer PPL, and third to fifth adhesive layers AL3 to AL5.

The window WIN, the window protection layer WP, and the impact absorbing layer ISL may be disposed on the electronic panel EP. The panel protection layer PPL and the support plate PLT may be disposed under the electronic panel EP.

The window WIN may be disposed on the impact absorbing layer ISL. The window WIN may protect the electronic panel EP from external scratches. The window WIN may have a property of being optically clear. The window WIN may include glass. However, without being limited thereto, the window WIN may include a synthetic resin film.

The window WIN may have a multi-layer structure or a single-layer structure. For example, the window WIN may include a plurality of synthetic resin films coupled by an adhesive or may include a glass substrate and a synthetic resin film coupled by an adhesive.

The window protection layer WP may be disposed on the window WIN. The window protection layer WP may include a flexible plastic material, such as polyimide (PI) or polyethylene terephthalate (PET).

The hard coating layer HC may be disposed on the upper surface of the window protection layer WP. The upper surface of the window protection layer WP may be coated with the hard coating layer HC.

The printed layer PIT may be disposed on the lower surface of the window protection layer WP. The printed layer PIT may be black in color. However, the color of the printed layer PIT is not limited thereto. The printed layer PIT may be adjacent to the periphery of the window WIN.

The impact absorbing layer ISL may be disposed on the electronic panel EP. The impact absorbing layer ISL may protect the electronic panel EP by absorbing external impact applied from above the display device DD toward the electronic panel EP. The impact absorbing layer ISL may be manufactured in the form of a stretchable film.

The impact absorbing layer ISL may include a flexible plastic material. For example, the impact absorbing layer ISL may include a flexible plastic material, such as polyimide or polyethylene terephthalate.

The panel protection layer PPL may be disposed under the electronic panel EP. The panel protection layer PPL may be disposed under the display panel DP. The panel protection layer PPL may protect the lower portion of the display panel DP. The panel protection layer PPL may include a flexible plastic material. For example, the panel protection layer PPL may include polyethylene terephthalate.

The first adhesive layer AL1 may be disposed between the window protection layer WP and the window WIN. The window protection layer WP and the window WIN may be bonded to each other by the first adhesive layer AL1. The first adhesive layer AL1 may cover the printed layer PIT.

The second adhesive layer AL2 may be disposed between the window WIN and the impact absorbing layer ISL. The window WIN and the impact absorbing layer ISL may be bonded to each other by the second adhesive layer AL2.

The third adhesive layer AL3 may be disposed between the impact absorbing layer ISL and the electronic panel EP. The impact absorbing layer ISL and the electronic panel EP may be bonded to each other by the third adhesive layer AL3.

The fourth adhesive layer AL4 may be disposed between the electronic panel EP and the panel protection layer PPL. The electronic panel EP and the panel protection layer PPL may be bonded to each other by the fourth adhesive layer AL4. The fifth adhesive layer AL5 may be disposed under the panel protection layer PPL.

The support plate PLT may be disposed under the panel protection layer PPL. The fifth adhesive layer AL5 may be disposed between the support plate PLT and the panel protection layer PPL. The support plate PLT and the panel protection layer PPL may be bonded to each other by the fifth adhesive layer AL5.

The support plate PLT may include a metallic material or a non-metallic material. For example, the support plate PLT may include stainless steel. In addition, without being limited thereto, the support plate PLT may include a fiber reinforced composite. The fiber reinforced composite may be carbon fiber reinforced plastic (CFRP) or glass fiber reinforced plastic (GFRP).

A plurality of openings OP may be defined in the portion of the support plate PLT that overlaps the folding area FA. The openings OP may be formed through portions of the support plate PLT in the third direction DR3. The openings OP may be arranged in (or may form) a lattice form or shape when viewed from above the plane.

The support plate PLT may include a first support plate PLT1, a second support plate PLT2, and a folding part PLT_F. For example, the boundaries between the first support plate PLT1, the second support plate PLT2, and the folding part PLT_F are illustrated by dotted lines on the support plate PLT.

The folding part PLT_F may be disposed between the first support plate PLT1 and the second support plate PLT2. The first support plate PLT1, the folding part PLT_F, and the second support plate PLT2 may be arranged in the first direction DR1. The openings OP may be defined in the folding part PLT_F.

The first support plate PLT1 may be disposed under the first non-folding area NFA1 and may overlap the first non-folding area NFA1. The second support plate PLT2 may be disposed under the second non-folding area NFA2 and may overlap the second non-folding area NFA2. The folding part PLT_F may be disposed under the folding area FA and may overlap the folding area FA.

The folding part PLT_F may have a curved portion CSP, a first extension EX1, a second extension EX2, a first inverse curvature portion ICV1, and a second inverse curvature portion ICV2. For example, the boundaries between the curved portion CSP, the first extension EX1, the second extension EX2, the first inverse curvature portion ICV1, and the second inverse curvature portion ICV2 are illustrated by dotted lines on the support plate PLT, and for convenience, the reference numerals thereof are illustrated above the display module DM with the dotted boundary lines extended upward.

The curved portion CSP, the first extension EX1, the second extension EX2, the first inverse curvature portion ICV1, and the second inverse curvature portion ICV2 may be arranged in the first direction DR1. For example, the curved portion CSP may be disposed at the center of the folding part PLT_F.

The curved portion CSP may be disposed between the first extension EX1 and the second extension EX2. The openings OP may be defined in the curved portion CSP. When the folding part PLT_F is folded, the curved portion CSP may be bent to have a curvature (e.g., a predetermined curvature). Because the openings OP are defined in the curved portion CSP, the flexibility of the curved portion CSP may be increased. Thus, the curved portion CSP may be easily folded.

The first extension EX1 may be disposed between the first inverse curvature portion ICV1 and the curved portion CSP. The second extension EX2 may be disposed between the second inverse curvature portion ICV2 and the curved portion CSP.

The first inverse curvature portion ICV1 may be disposed between the first support plate PLT1 and the first extension EX1. The second inverse curvature portion ICV2 may be disposed between the second support plate PLT2 and the second extension EX2.

The fifth adhesive layer AL5 may not be disposed in the area overlapping the curved portion CSP. The fifth adhesive layer AL5 may be open in the area overlapping (e.g., may have an opening corresponding to) the curved portion CSP.

The first to fifth adhesive layers AL1 to AL5 may include a transparent adhesive, such as a pressure sensitive adhesive (PSA) or an optically clear adhesive (OCA), but the type of adhesive is not limited thereto.

Hereinafter, “thickness” may represent or refer to a numerical value measured in the third direction DR3, and “width” may represent or refer to a numerical value measured in the first direction DR1 or the second direction DR2, which are horizontal directions.

For example, the hard coating layer HC may have a thickness of about 5 micrometers (μm), the window protection layer WP may have a thickness of about 65 micrometers (μm), and the first adhesive layer AL1 may have a thickness of about 50 micrometers (μm). The window WIN may have a thickness of about 30 micrometers (μm), the second adhesive layer AL2 may have a thickness of about 50 micrometers (μm), and the impact absorbing layer ISL may have a thickness of about 23 micrometers (μm).

The third adhesive layer AL3 may have a thickness of about 50 micrometers (μm), the electronic panel EP may have a thickness of about 30 micrometers (μm), and the fourth adhesive layer AL4 may have a thickness of about 25 micrometers (μm). The panel protection layer PPL may have a thickness of about 50 micrometers (μm), and the fifth adhesive layer AL5 may have a thickness of about 16 micrometers (μm). The support plate PLT may have a thickness of about 170 micrometers (μm).

The width of the first adhesive layer AL1 may be smaller than the width of the window protection layer WP. The widths of the window WIN and the second adhesive layer AL2 may be smaller than the width of the first adhesive layer AL1. The width of the second adhesive layer AL2 may be smaller than the width of the window WIN.

The electronic panel EP, the impact absorbing layer ISL, the panel protection layer PPL, the third adhesive layer AL3, and the fourth adhesive layer AL4 may have the same width. The widths of the electronic panel EP, the impact absorbing layer ISL, the panel protection layer PPL, the third adhesive layer AL3, and the fourth adhesive layer AL4 may be greater than the width of the first adhesive layer AL1. The widths of the electronic panel EP, the impact absorbing layer ISL, the panel protection layer PPL, the third adhesive layer AL3, and the fourth adhesive layer AL4 may be smaller than the width of the window protection layer WP.

The peripheries (e.g., the peripheral edges) of the electronic panel EP, the impact absorbing layer ISL, the panel protection layer PPL, the third adhesive layer AL3, and the fourth adhesive layer AL4 may overlap one another. The peripheries of the electronic panel EP, the impact absorbing layer ISL, the panel protection layer PPL, the third adhesive layer AL3, and the fourth adhesive layer AL4 may be located outwardly of (e.g., beyond) the periphery of the first adhesive layer AL1 and may be disposed inwardly of the periphery of the window protection layer WP.

The periphery of the window WIN may be disposed inwardly of the periphery of the first adhesive layer AL1. The periphery of the second adhesive layer AL2 may be disposed inwardly of the periphery of the window WIN. The periphery of the fifth adhesive layer AL5 may be disposed inwardly of the periphery of the panel protection layer PPL.

The width of the support plate PLT may be substantially the same as the width of the electronic panel EP. The periphery of the support plate PLT may overlap the periphery of the electronic panel EP.

The window protection layer WP may extend outwardly further than (e.g., may extend beyond) the electronic panel EP, the window WIN, and the support plate PLT. The periphery of the window protection layer WP may be disposed outwardly of the peripheries of the electronic panel EP, the window WIN, and the support plate PLT.

The electronic panel EP may extend to the bending area BA and the second area AA2. The panel protection layer PPL and the fourth adhesive layer AL4 may not be disposed under the bending area BA. The panel protection layer PPL and the fourth adhesive layer AL4 may be disposed under the second area AA2 of the electronic panel EP. The data driver DDV may be disposed in the second area AA2 of the electronic panel EP.

A printed circuit board PCB may be disposed in the second area AA2 adjacent to the end of the second area AA2. The above-described timing controller may be disposed on the printed circuit board PCB. The printed circuit board PCB may be spaced apart from the data driver DDV and may be connected to the second area AA2.

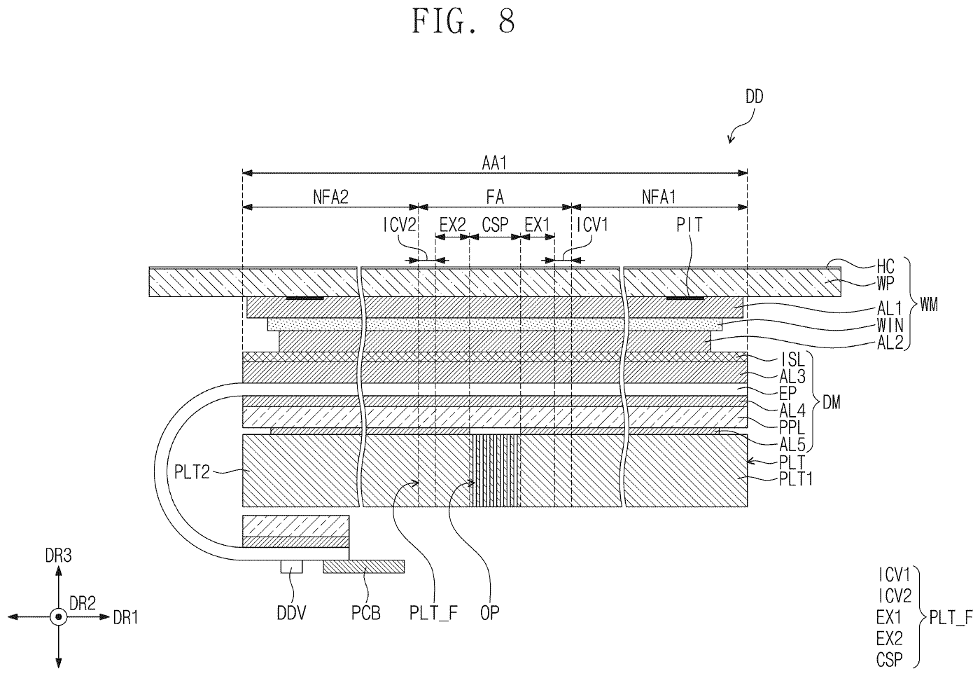

FIG. 8 is a view illustrating the bending area illustrated in FIG. 7 in a bent state.

Referring to FIG. 8, the bending area BA may be bent to have a curvature (e.g., a predetermined curvature). As the bending area BA is bent, the second area AA2 may be disposed under the first area AA1. Accordingly, the data driver DDV and the printed circuit board PCB may be disposed under the first area AA1.

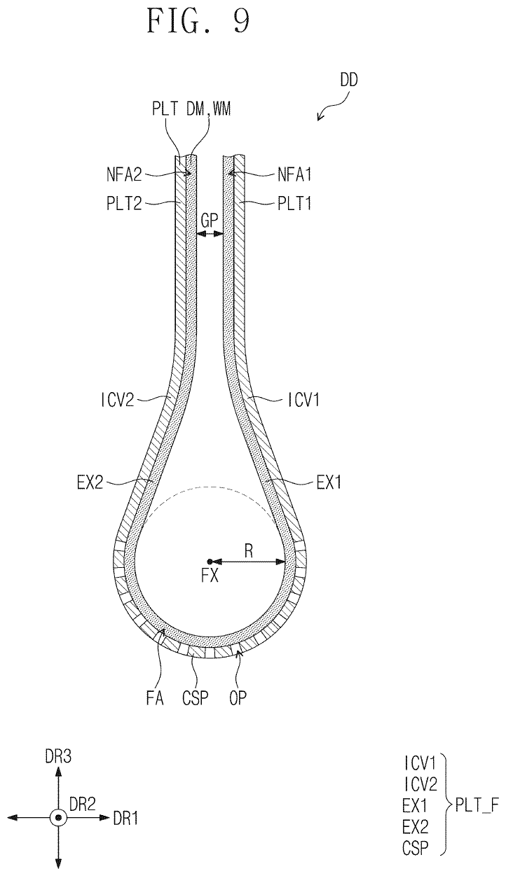

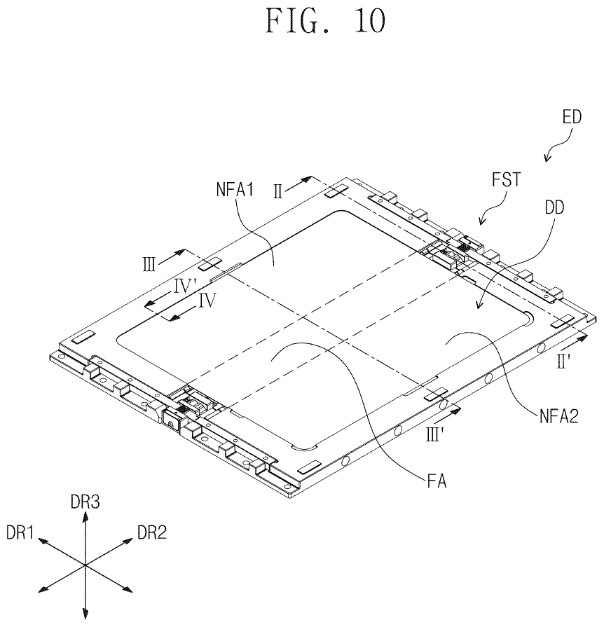

FIG. 9 is a view illustrating the display device illustrated in FIG. 7 in a folded state.

In FIG. 9, the bending area BA and the second area AA2 are omitted and the display module DM and the window module WM are illustrated as a single layer for convenience of description.

Referring to FIG. 9, the support plate PLT may be folded about the folding axis FX. The support plate PLT may be folded in a dumbbell shape. As the support plate PLT is folded, the display module DM may be folded together with the support plate PLT.

The folding part PLT_F may be folded about the folding axis FX, and the support plate PLT may be folded accordingly. When the folding part PLT_F is folded, the curved portion CSP may be bent to have a curvature (e.g., a predetermined curvature). For example, the folding area FA of the display module DM of the curved portion CSP may be bent to have the radius of curvature R.

The first inverse curvature portion ICV1 may be bent opposite to the curved portion CSP. The second inverse curvature portion ICV2 may be bent opposite to the curved surface portion CSP. The second inverse curvature portion ICV2 may have a shape symmetrical to that of the first inverse curvature portion ICV1.

When the folding part PLT_F is folded, the first support plate PLT1 and the second support plate PLT2 may remain flat. Accordingly, the first non-folding area NFA1 and the second non-folding area NFA2 may be maintained in a flat state by the first support plate PLT1 and the second support plate PLT2.

When the folding part PLT_F is folded, the distance GP between the first non-folding area NFA1 and the second non-folding area NFA2 in the first direction DR1 may be smaller than the diameter of the circle having the radius of curvature R.

The first extension EX1 may remain flat between the curved portion CSP and the first inverse curvature portion ICV1. The first extension EX1 may extend flat from the first inverse curvature portion ICV1 toward the curved portion CSP.

The second extension EX2 may remain flat between the curved portion CSP and the second inverse curvature portion ICV2. The second extension EX2 may extend flat from the second inverse curvature portion ICV2 toward the curved portion CSP.

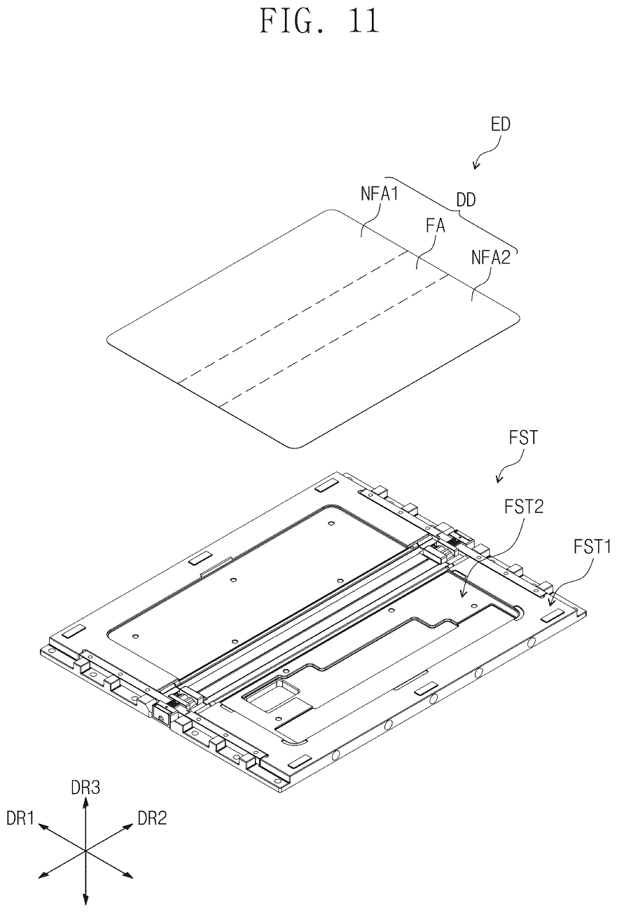

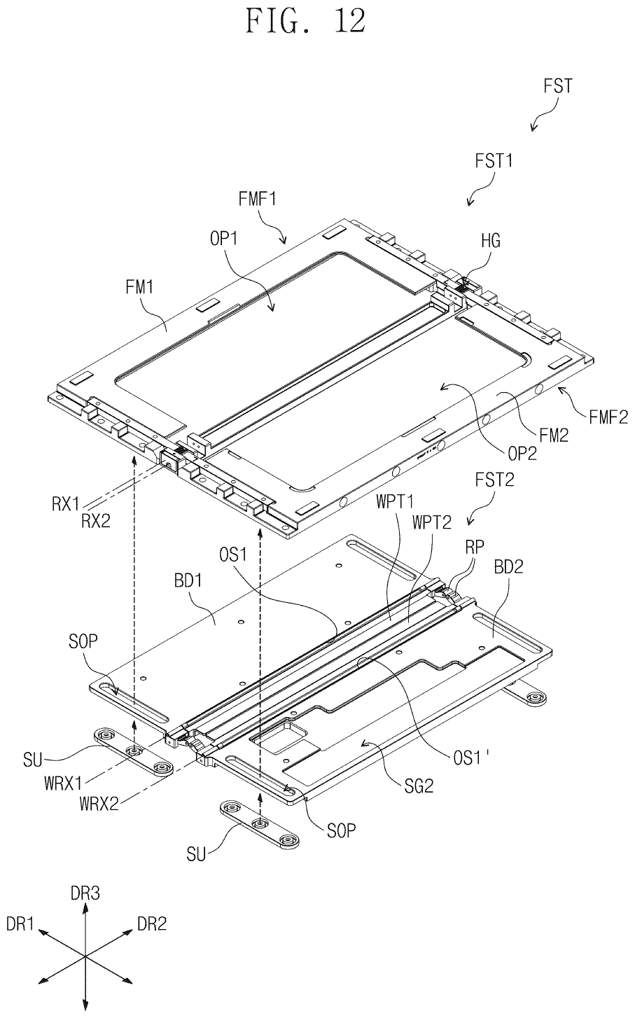

FIG. 10 is a perspective view of an electronic device including the folding set according to an embodiment of the present disclosure. FIG. 11 is an exploded perspective view of the electronic device illustrated in FIG. 10.

In FIG. 11, the electronic device ED is divided into the folding set FST and the display device DD.

Referring to FIGS. 10 and 11, the electronic device ED may include the folding set FST and the display device DD disposed on the folding set FST. The folding set FST may accommodate the display device DD, and the display device DD may be attached to the folding set FST. The folding set FST may fold the display device DD. The folding set FST may be folded about biaxial rotational axes overlapping the folding area FA to fold the display device DD. This configuration will be described below in more detail.

The folding set FST may be defined as a folding mechanism for folding the display device DD. The folding set FST may be a component of the electronic device ED. However, without being limited thereto, the folding set FST may be used as a separate test or evaluation mechanism rather than a component of the electronic device ED.

For example, a plurality of display devices DD may be manufactured, and one display device DD may be attached to the folding set FST as a sample display device DD. Thereafter, the durability of the display device DD may be tested by repeatedly folding and unfolding the sample display device DD by the folding set FST.

However, without being limited thereto, the electronic device ED may be manufactured by attaching the display device DD to the folding set FST and may be sold to consumers as a product. For example, the folding set FST may be diversely used as a component of the electronic device ED or as a test mechanism.

The folding set FST may include a first folding set FST1 and a second folding set FST2 coupled to the first folding set FST1. The first folding set FST1 and the second folding set FST2 may be coupled to slide (e.g., may be slidably coupled) relative to each other and may rotate about biaxial rotational axes to fold the display device DD. This configuration will be described below in more detail.

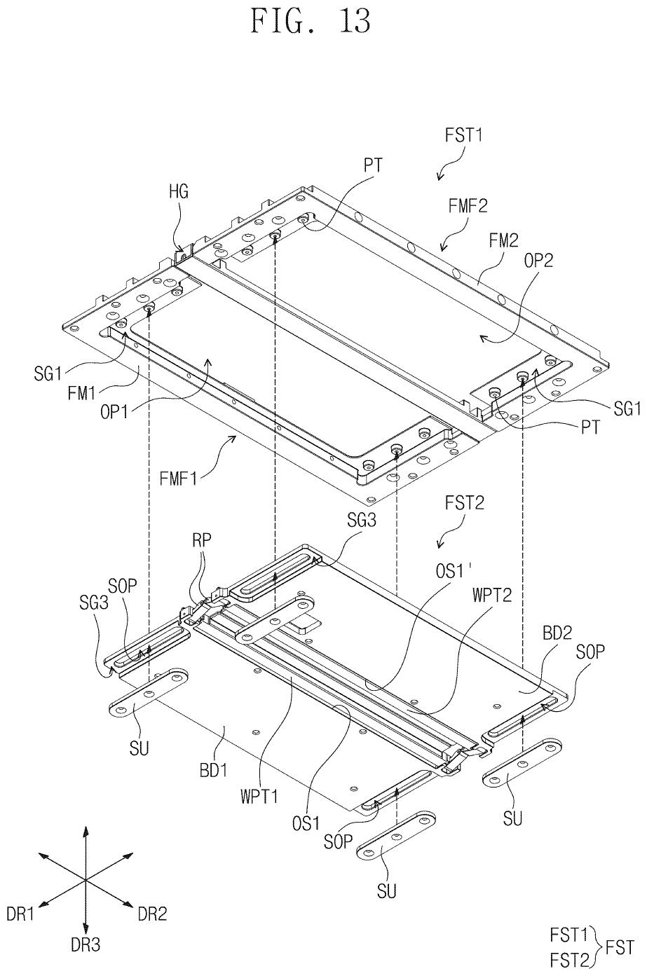

FIG. 12 is an exploded perspective view illustrating a front side of the folding set illustrated in FIG. 11. FIG. 13 is an exploded perspective view illustrating a rear side of the folding set illustrated in FIG. 11.

For example, in FIGS. 12 and 13, the folding set FST is divided into the first folding set FST1, the second folding set FST2, and sliding units SU.

Referring to FIGS. 12 and 13, the folding set FST may include the first folding set FST1, the second folding set FST2 disposed under the first folding set FST1, and the plurality of sliding units SU disposed under the second folding set FST2.

The first folding set FST1 may include a first frame FM1, a second frame FM2, and a hinge HG. The first frame FM1 and the second frame FM2 may be spaced apart from each other in the first direction DR1. The first frame FM1 and the second frame FM2 may have symmetrical shapes in the first direction DR1.

The hinge HG may be disposed between the first frame FM1 and the second frame FM2. The hinge HG may extend in the second direction DR2. The hinge HG may be coupled to the first frame FM1 and the second frame FM2. The hinge HG may define first biaxial rotational axes RX1 and RX2 that are spaced apart from each other in the first direction DR1 and that extend parallel to each other in the second direction DR2.

The first frame FM1 and the hinge HG may be coupled with each other to define a first frame shape FMF1 having a first opening OP1 defined therein. The second frame FM2 and the hinge HG may be coupled with each other to define a second frame shape FMF2 having a second opening OP2 defined therein.

The first non-folding area NFA1 of the display device DD may overlap the first opening OP1 defined by the first frame FM1. The second non-folding area NFA2 of the display device DD may overlap the second opening OP2 defined by the second frame FM2. The hinge HG may overlap the folding area FA of the display device DD. The display device DD may be disposed in the first opening OP1 and the second opening OP2.

The second folding set FST2 may include a first body BD1, a second body BD2, a first wing plate WPT1, a second wing plate WPT2, and a plurality of rotating parts RP. The first body BD1 and the second body BD2 may be spaced apart from each other in the first direction DR1. The first wing plate WPT1 and the second wing plate WPT2 may be disposed adjacent to each other in the first direction DR1. The first wing plate WPT1 and the second wing plate WPT2 may be disposed between the first body BD1 and the second body BD2.

The first body BD1 may have a flat shape corresponding to the plane defined by the first direction DR1 and the second direction DR2. The second body BD2 may have a flat shape corresponding to the plane defined by the first direction DR1 and the second direction DR2.

The first body BD1 may be disposed under the first frame FM1 and may overlap the first frame FM1. The first body BD1 may be exposed by (or exposed through) the first opening OP1. The first body BD1 may overlap the first non-folding area NFA1.

The second body BD2 may be disposed under the second frame FM2 and may overlap the second frame FM2. The second body BD2 may be exposed by the second opening OP2. The second body BD2 may overlap the second non-folding area NFA2.

The first wing plate WPT1 and the second wing plate WPT2 may extend in the second direction DR2. The first wing plate WPT1 and the second wing plate WPT2 may overlap the folding area FA. The first wing plate WPT1 and the second wing plate WPT2 may have symmetrical shapes in the first direction DR1.

The first wing plate WPT1 may be disposed adjacent to the first body BD1. The first wing plate WPT1 may be coupled to a first side OS1 of the first body BD1 that faces the second body BD2. The first wing plate WPT1 may be rotatably coupled to the first side OS1 of the first body BD1. The first wing plate WPT1 may rotate about a first wing rotational axis WRX1 that is defined adjacent to the first side OS1 of the first body BD1 and that extends in the second direction DR2.

The second wing plate WPT2 may be disposed adjacent to the second body BD2. The second wing plate WPT2 may be coupled to a first side OS1′ of the second body BD2 that faces the first body BD1. The second wing plate WPT2 may be rotatably coupled to the first side OS1′ of the second body BD2. The second wing plate WPT2 may rotate about a second wing rotational axis WRX2 that is defined adjacent to the first side OS1′ of the second body BD2 and that extends in the second direction DR2.

The first wing plate WPT1 and the second wing plate WPT2 may be connected to the first body BD1 and the second body DB2 by fastening units (e.g., fasteners), such as pins.

The rotating parts RP may be disposed adjacent to opposite sides of the first body BD1 and the second body BD2 opposite to each other in the second direction DR2 and may be connected to the first sides OS1 and OS1′ of the first body BD1 and the second body BD2. The first wing plate WPT1 and the second wing plate WPT2 may be disposed between the rotating parts RP in the second direction DR2.

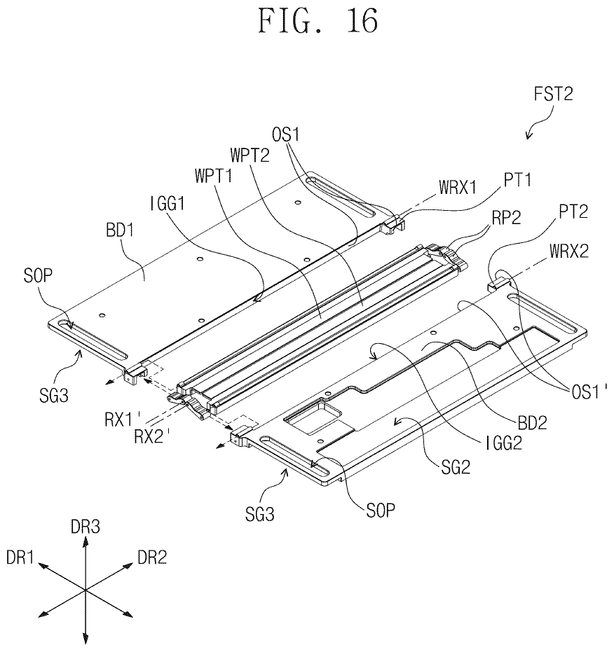

In FIG. 16 and the following drawings, the rotating parts RP are referred to as second rotating parts RP2 (see, e.g., FIG. 16). The rotating parts RP may be connected to the first body BD1 and the second body BD2 by fastening units (e.g., fasteners), such as pins.

First seating grooves SG1 may be defined i the lower surfaces of the first frame FM1 and the second frame FM2, respectively. The first seating grooves SG1 may be defined adjacent to the first opening OP1 and the second opening OP2. The first seating grooves SG1 may be defined (or may extend) continuously from the first opening OP1 and the second opening OP2.

The first body BD1 and the second body BD2 may be disposed in the first seating grooves SG1. Sides of the first body BD1 other than the first side OS1 of the first body BD1 may be disposed in the first seating groove SG1 of the first frame FM1. Sides of the second body BD2 other than the first side OS1′ of the second body BD2 may be disposed in the first seating groove SG1 of the second frame FM2. Portions of the first body BD1 and the second body BD2 that are not disposed in the first seating grooves SG1 may be exposed upwardly by the first opening OP1 and the second opening OP2.

A second seating groove SG2 may be defined in the upper surface of the second body BD2. When the bending area BA is bent, as illustrated in FIG. 8, so that the second area AA2 is disposed under the first area AA1, the second area AA2 and the printed circuit board PCB may be disposed in the second seating groove SG2.

Third seating grooves SG3 may be defined in the lower surfaces of the first body BD1 and the second body BD2 that are adjacent to the opposite sides of the first body BD1 and the second body BD2 opposite to each other in the second direction DR2. The third seating grooves SG3 may be defined from the opposite sides of the first body BD1 and the second body BD2 opposite to each other in the second direction DR2. The third seating grooves SG3 may extend in the second direction DR2.

The sliding units SU may be disposed under the first body BD1 and the second body BD2 and may overlap the first body BD1 and the second body BD2. The sliding units SU may be disposed adjacent to the opposite sides of the first body BD1 and the second body BD2 opposite to each other in the second direction DR2. The sliding units SU may be disposed in the third seating grooves SG3, respectively.

A plurality of sliding openings SOP may be defined in the first body BD1 and the second body BD2. The sliding openings SOP may extend in the first direction DR1. The sliding openings SOP may be defined adjacent to the opposite sides of the first body BD1 and the second body BD2 opposite to each other in the second direction DR2. The sliding openings SOP may be defined in the portions of the first body BD1 and the second body BD2 at where the third seating grooves SG3 are defined.

The sliding openings SOP may not overlap the first opening OP1 and the second opening OP2. The sliding openings SOP may overlap the portions of the first frame FM1 and the second frame FM2 at where the first seating grooves SG1 are defined.

The sliding units SU may be disposed to overlap the sliding openings SOP, respectively. When viewed from above the plane, the area of each of the sliding units SU may be greater than the area of each of the sliding openings SOP.

The sliding units SU may be connected to the first frame FM1 and the second frame FM2 through the sliding openings SOP. The first frame FM1 and the second frame FM2 may include a plurality of protrusions PT protruding toward the sliding units SU from the lower surfaces of the first frame FM1 and the second frame FM2 at where the first seating grooves SG1 are defined. The protrusions PT may be disposed in the sliding openings SOP.

The sliding units SU may be connected to the protrusions PT. The sliding units SU may be connected to the first frame FM1 and the second frame FM2 through the protrusions PT. The protrusions PT may move in the sliding openings SOP in the first direction DR1 along the sliding openings SOP. This configuration will be described below in more detail.

The sliding units SU may be connected to the protrusions PT by fastening units (e.g., fasteners), such as screws.

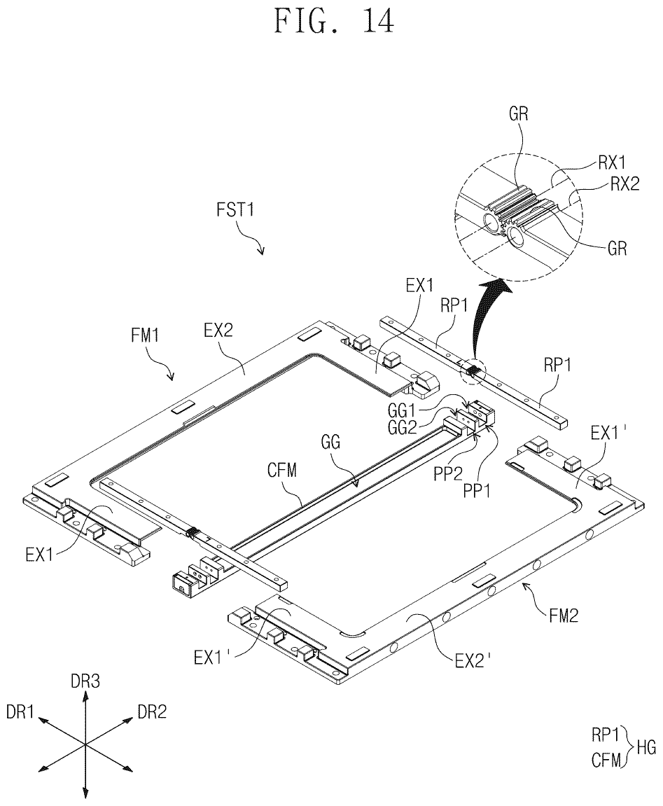

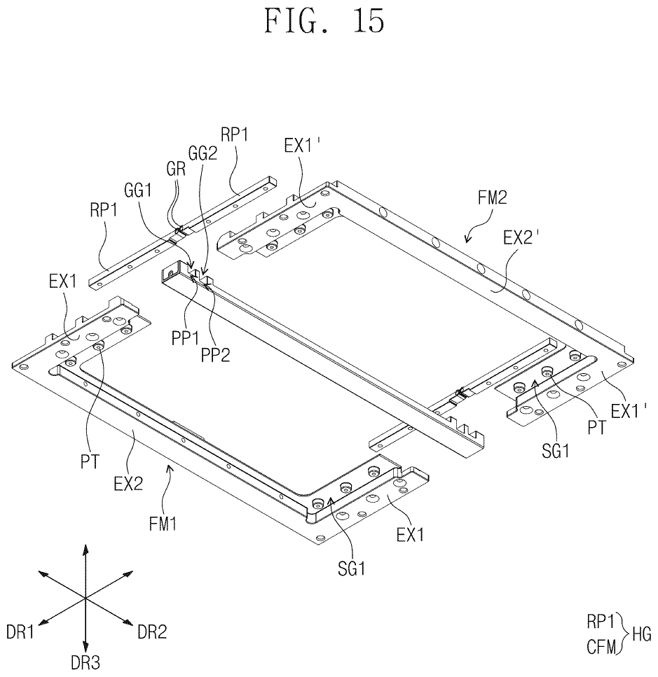

FIG. 14 is an exploded perspective view illustrating a front side of the first folding set illustrated in FIG. 12. FIG. 15 is an exploded perspective view illustrating a rear side of the first folding set illustrated in FIG. 13.

Referring to FIGS. 12, 13, 14, and 15, the first frame FM1 may include a plurality of first extensions EX1 that are spaced apart from each other in the second direction DR2 and that extend parallel to each other in the first direction DR1 and a second extension EX2 that extends in the second direction DR2. The second frame FM2 may include a plurality of first extensions EX1′ that are spaced apart from each other in the second direction DR2 and that extend parallel to each other in the first direction DR1 and a second extension EX2′ that extends in the second direction DR2.

First sides of the first extensions EX1 and first sides of the first extensions EX1′ may face each other in the first direction DR1. The second extension EX2 may extend in the second direction DR2 from second sides of the first extensions EX1 opposite to the first sides of the first extensions EX1. The second extension EX2′ may extend in the second direction DR2 from second sides of the first extensions EX1′ opposite to the first sides of the first extensions EX1′.

The first seating grooves SG1 may be defined in the lower surfaces of the first extensions EX1, the lower surface of the second extension EX2, the lower surfaces of the first extensions EX1′, and the lower surface of the second extension EX2′. The protrusions PT may protrude downwardly from the first extensions EX1 and the first extensions EX1′.

The hinge HG may include a central frame CFM and a plurality of first rotating parts RP1. The central frame CFM may be disposed between the first extensions EX1 and the first extensions EX1′ and may extend in the second direction DR2. The central frame CFM may be connected to the first frame FM1 and the second frame FM2 through the first rotating parts RP1.

The first opening OP1 and the first frame shape FMF1 described above may be defined by the central frame CFM and the first frame FM1 connected with each other. The second opening OP2 and the second frame shape FMF2 described above may be defined by the central frame CFM and the second frame FM2 connected with each other.

Portions of the central frame CFM adjacent to opposite sides of the central frame CFM opposite to each other in the second direction DR2 may be defined as first portions PP1. Portions of the central frame CFM disposed inwardly of the first portions PP1 may be defined as second portions PP2. First grooves GG1 may be defined in the upper surfaces of the first portions PP1, and second grooves GG2 may be defined in the upper surfaces of the second portions PP2.

A groove GG may be defined in a portion of the central frame CFM between the second portions PP2. The groove GG may extend in the second direction DR2. The groove GG may be defined adjacent to the first opening OP1 and the second opening OP2 in the first direction DR1.

The first rotating parts RP1 may extend in the first direction DR1. The first rotating parts RP1 may be connected to the first frame FM1 and the second frame FM2. For example, the first rotating parts RP1 may be connected to the first extensions EX1 of the first frame FM1 and the first extensions EX1′ of the second frame FM2.

First sides of the first rotating parts RP1 that face each other in the first direction DR1 may include gears GR and may be disposed to be engaged with each other. The first rotating parts RP1 may be rotatably coupled to the first portions PP1 of the central frame CFM. The first sides of the first rotating parts RP1 may be disposed in the first grooves GG1 defined in the first portions PP1 and may be rotatably coupled and connected to the central frame CFM.

The first rotating parts RP1 may define the first biaxial rotational axes RX1 and RX2. The first biaxial rotational axes RX1 and RX2 may be adjacent to the first sides of the first rotating parts RP1 and may be defined as rotational axes of the gears GR. The first rotating parts RP1 may rotate about the first biaxial rotational axes RX1 and RX2. The first biaxial rotational axes RX1 and RX2 may overlap the central frame CFM.

The first rotating parts RP1 may be connected to the first frame FM1, the second frame FM2, and the central frame CFM by fastening units (e.g., fasteners), such as pins.

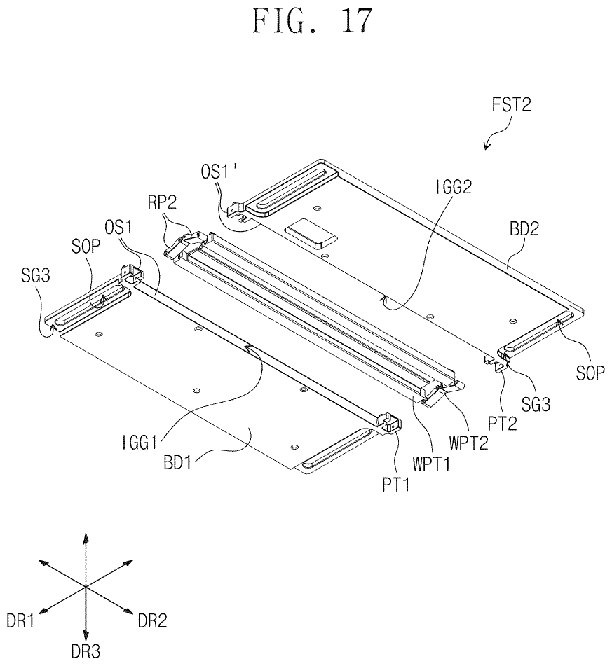

FIG. 16 is an exploded perspective view illustrating a front side of the second folding set illustrated in FIG. 12. FIG. 17 is an exploded perspective view illustrating a rear side of the second folding set illustrated in FIG. 13.

Referring to FIGS. 12, 13, 16, and 17, the first body BD1 may include first protrusions PT1 protruding toward the second body BD2 from opposite sides of the first side OS1 opposite to each other in the second direction DR2. The second body BD2 may include second protrusions PT2 protruding toward the first body BD1 from opposite sides of the first side OS1′ opposite to each other in the second direction DR2.

Depending on this structure, a first inner groove IGG1 may be defined between the first protrusions PT1. In addition, a second inner groove IGG2 may be defined between the second protrusions PT2.

A first side of the first wing plate WPT1 that faces the first side OS1 of the first body BD1 may be disposed in the first inner groove IGG1. A first side of the second wing plate WPT2 that faces the first side OS1′ of the second body BD2 may be disposed in the second inner groove IGG2.

The first wing plate WPT1 may be rotatably coupled to the first protrusions PT1. The above-described first wing rotational axis WRX1 may be defined by the first wing plate WPT1 and the first protrusions PT1 rotatably coupled with each other.

The second wing plate WPT2 may be rotatably coupled to the second protrusions PT2. The above-described second wing rotational axis WRX2 may be defined by the second wing plate WPT2 and the second protrusions PT2 rotatably coupled with each other.

The second rotating parts RP2 (the above-described rotating parts RP) may be disposed adjacent to the first protrusions PT1 and the second protrusions PT2 in the first direction DR1. The second rotating parts RP2 may be connected to the first protrusions PT1 and the second protrusions PT2.

Referring to FIGS. 11, 12, 14, 16, and 17, the first wing plate WPT1 and the second wing plate WPT2 may be disposed on the central frame CFM. For example, the first wing plate WPT1 and the second wing plate WPT2 may be disposed above the groove GG defined in the central frame CFM.

First sides of the second rotating parts RP2 that face each other in the first direction DR1 may be disposed adjacent to each other. Second sides of the second rotating parts RP2 may be connected to the first protrusions PT1 and the second protrusions PT2. The second sides of the second rotating parts RP2 may be disposed in grooves that are defined in the first protrusions PT1 and the second protrusions PT2 and may be connected to the first protrusions PT1 and the second protrusions PT2.

The second rotating parts RP2 may be rotatably coupled to the second portions PP2 of the central frame CFM. The first sides of the second rotating parts RP2 may be disposed in the second grooves GG2 defined in the second portions PP2 and may be rotatably coupled to the central frame CFM.

The second rotating parts RP2 may define second biaxial rotational axes RX1′ and RX2′. The second biaxial rotational axes RX1′ and RX2′ may be spaced apart from each other in the first direction DR1 and may extend parallel to each other in the second direction DR2. The second biaxial rotational axes RX1′ and RX2′ may be defined adjacent to the first sides of the second rotating parts RP2. The second rotating parts RP2 may rotate about the second biaxial rotational axes RX1′ and RX2′. The second biaxial rotational axes RX1′ and RX2′ may overlap the central frame CFM.

The second rotating parts RP2 may be connected to the first protrusions PT1, the second protrusions PT2, and the central frame CFM by fastening units (e.g., fasteners), such as pins.

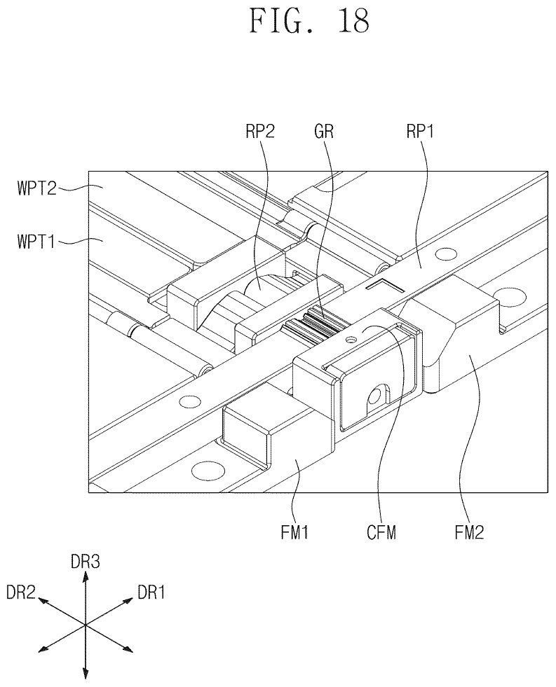

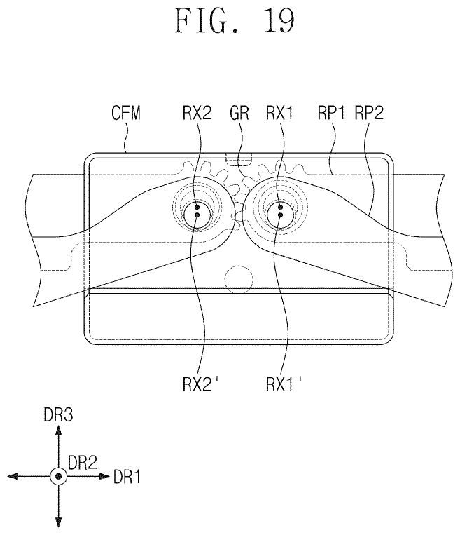

FIG. 18 is an enlarged view illustrating a portion of the folding set at where a pair of first rotating parts and a pair of second rotating parts are disposed adjacent to each other in FIG. 11. FIG. 19 is a side view of the first rotating parts and the second rotating parts as viewed in the second direction.

For example, FIG. 19 illustrates a state in which the second rotating parts RP2 are disposed in front and the first rotating parts RP1 are disposed behind the second rotating parts RP2. The second rotating parts RP2 are illustrated in solid lines, and hidden portions of the first rotating parts RP1 disposed behind are illustrated in dotted lines.

Referring to FIGS. 18 and 19, the first biaxial rotational axes RX1 and RX2 defined by the first rotating parts RP1 may be spaced part from the second biaxial rotational axes RX1′ and RX2′ defined by the second rotating parts RP2 without overlapping the second biaxial rotational axes RX1′ and RX2′. The second biaxial rotational axes RX1′ and RX2′ may be disposed below the first biaxial rotational axes RX1 and RX2.

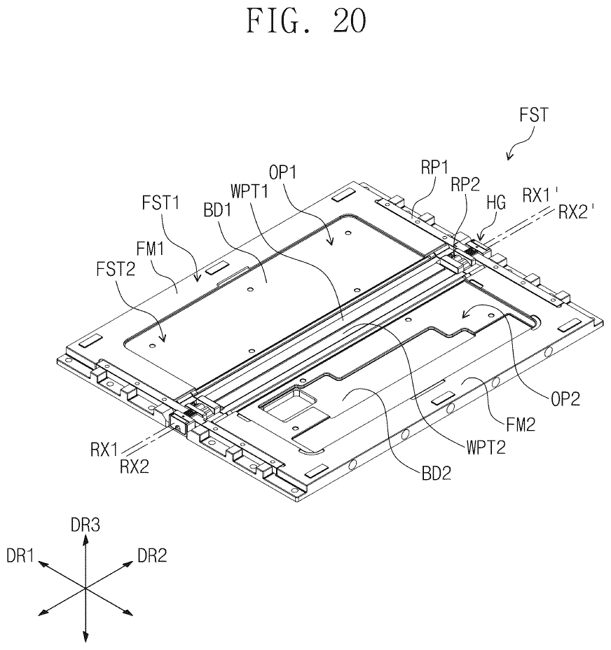

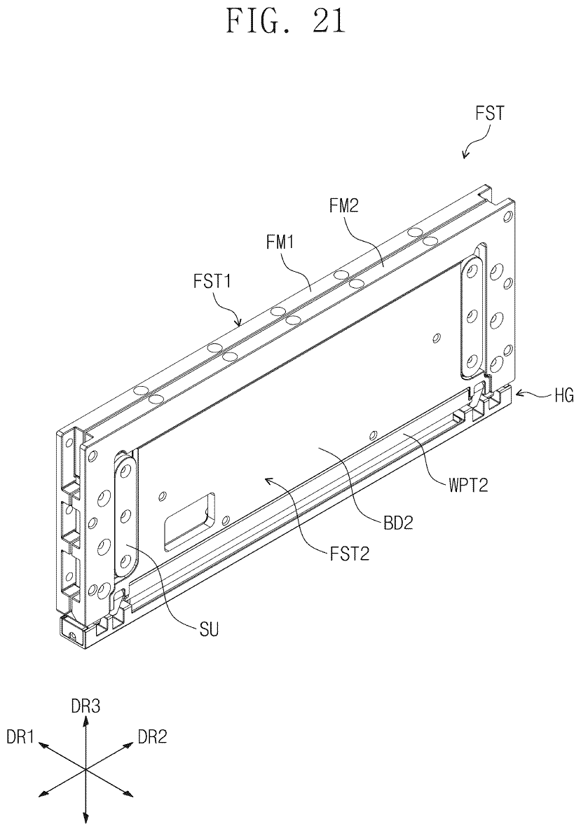

FIG. 20 is a view illustrating the folding set illustrated in FIG. 11 in an unfolded state. FIG. 21 is a view illustrating the folding set illustrated in FIG. 11 in a folded state.

Referring to FIGS. 10, 11, 20, and 21, the display device DD may be disposed on the second folding set FST2 in the first opening OP1 and the second opening OP2. The display device DD may be disposed on the first body BD1, the second body DB2, the first wing plate WPT1, and the second wing plate WPT2.

The folding set FST may be folded by rotating about the first biaxial rotational axes RX1 and RX2. The first rotating parts RP1 may rotate about the first biaxial rotational axes RX1 and RX2, and the folding set FST may be folded accordingly. The second rotating parts RP2 may rotate about the second biaxial rotational axes RX1′ and RX2′.

As the folding set FST is folded, the first frame FM1 and the second frame FM2 may be disposed to face each other, and the first body DB1 and the second body BD2 may be disposed to face each other. Depending on this operation, the display device DD attached to the folding set FST may be folded.

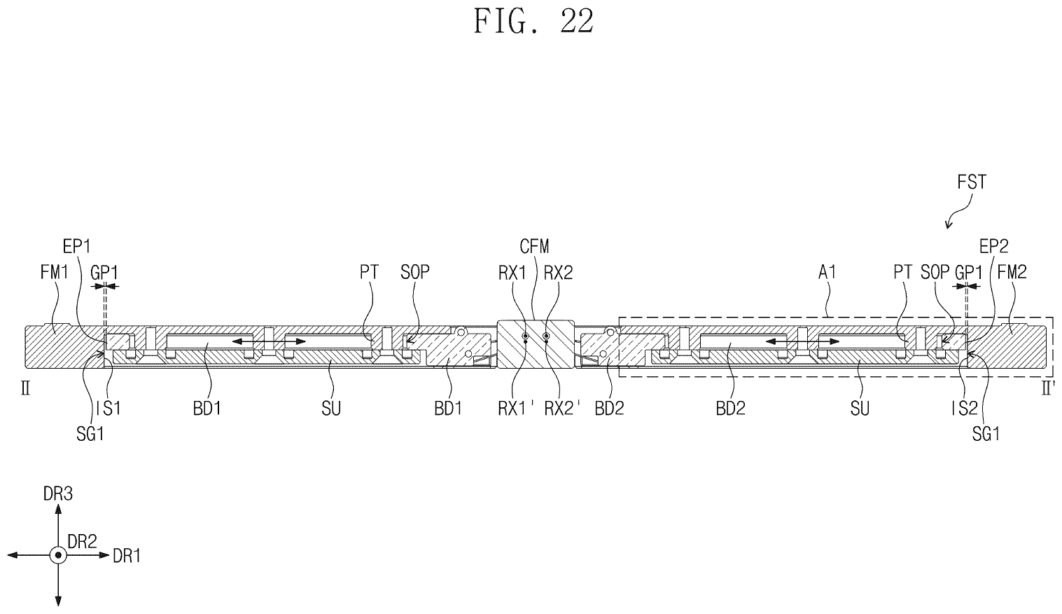

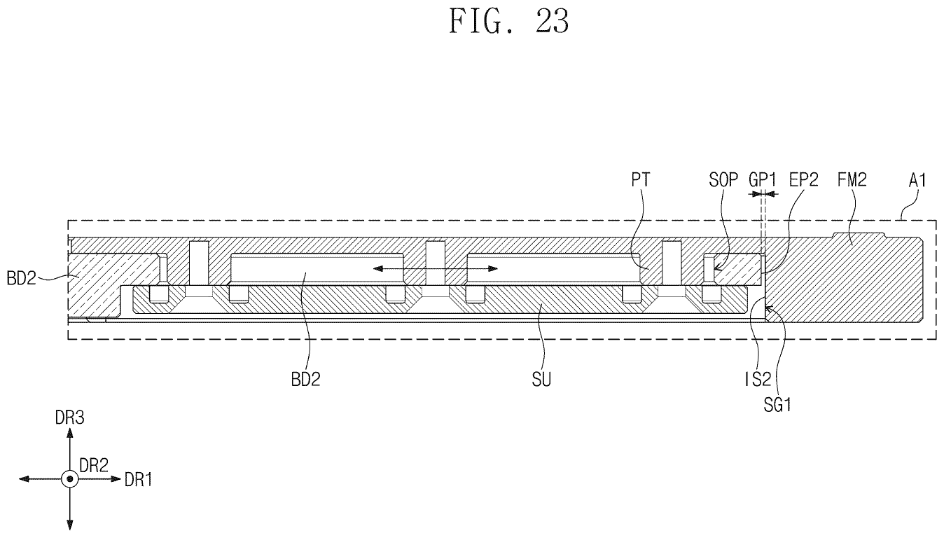

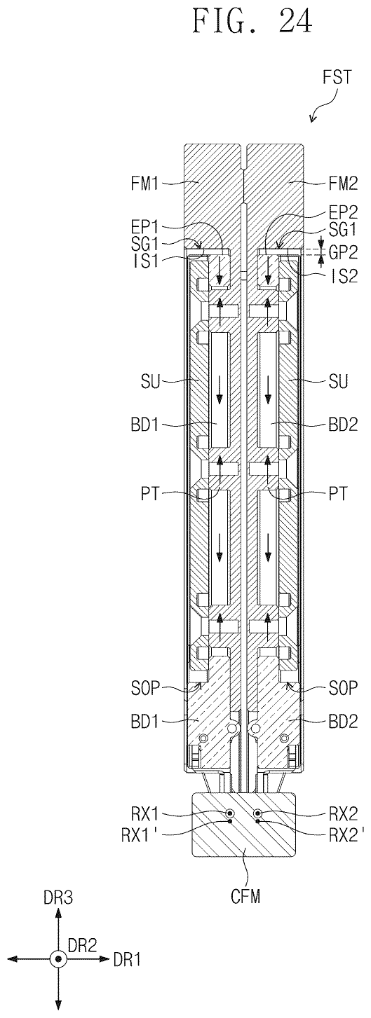

FIG. 22 is a sectional view taken along the line II-II′ in FIG. 10. FIG. 23 is an enlarged view of the first area A1 in FIG. 22. FIG. 24 is a view illustrating a folded state of the folding set illustrated in FIG. 22.

Referring to FIGS. 22, 23, and 24, the sliding units SU may be disposed in the first seating grooves SG1, and the protrusions PT may be disposed in the sliding openings SOP. The sliding units SU may be connected to the protrusions PT and, accordingly, may be connected to the first frame FM1 and the second frame FM2.

The sliding units SU may be connected to the protrusions PT, and the first body BD1 and the second body BD2 may be disposed between the sliding units SU and the first and second frames FM1 and FM2. Because the sliding units SU have a larger area than the sliding openings SOP, the first body BD1 and the second body BD2 may be stably disposed between the sliding units SU and the first and second frames FM1 and FM2.

A first end EP1 of the first body BD1 that faces toward the outside may face a first inner surface IS1 of the first frame FM1 at where the first seating groove SG1 is defined. A second end EP2 of the second body BD2 that faces toward the outside may face a second inner surface IS2 of the second frame FM2 at where the first seating groove SG1 is defined.

The first end EP1 of the first body BD1 may be defined as a second side of the first body BD1 opposite to the first side OS1 of the first body BD1. The second end EP2 of the second body BD2 may be defined as a second side of the second body BD2 opposite to the first side OS1′ of the second body BD2.

Referring to FIGS. 22 and 24, when the folding set FST is folded and unfolded by rotating about the first biaxial rotational axes RX1 and RX2, the protrusions PT may move along the sliding openings SOP. For example, when the first folding set FST1 is folded and unfolded by the hinge HG, the protrusions PT may move along the sliding openings SOP. Depending on the movement of the protrusions PT, the sliding units SU, the first frame FM1, and the second frame FM2 may move together in the extension direction of the sliding openings SOP.

The first body BD1 and the second body BD2 may also move relative to the protrusions PT through the sliding openings SOP. For example, the first body BD1 and the second body BD2 may also move relative to the sliding units SU, the first frame FM1, and the second frame FM2 through the sliding openings SOP. Accordingly, the first folding set FST1 and the second folding set FST2 may be coupled to slide relative to each other.

Referring to FIG. 22, when the folding set FST is unfolded, the gap between the first end EP1 and the first inner surface IS1 and the gap between the second end EP2 and the second inner surface IS2 may have a first gap GP1.

Referring to FIG. 24, when the folding set FST is folded by rotating about the first biaxial rotational axes RX1 and RX2, the protrusions PT and the first and second bodies BD1 and BD2 may move relative to each other.

The first body BD1 and the second body BD2 may move toward the central portion of the folding set FST when compared to (or relative to) the protrusions PT. For example, the first body BD1 and the second body BD2 may move toward the central portion of the folding set FST when compared to the sliding units SU, the first frame FM1, and the second frame FM2.

The protrusions PT may move away from the central portion of the folding set FST when compared to the first body BD1 and the second body BD2. For example, the sliding units SU, the first frame FM1, and the second frame FM2 may move away from the central portion of the folding set FST when compared to the first body BD1 and the second body BD2.

According to the sliding operation, the first folding set FST1 may move inwardly, for example, toward the central portion of the folding set FST when compared to the second folding set FST2. As described above, the first folding set FST1 may be rotated about the first biaxial rotational axes RX1 and RX2 by the first rotating parts RP1. However, the second rotating parts RP2 of the second folding set FST2 may rotate about the second biaxial rotational axes RX1′ and RX2′.

When the folding set FST is folded, the gap between the first end EP1 and the first inner surface IS1 and the gap between the second end EP2 and the second inner surface IS2 may have a second gap GP2, the second gap GP2 being greater than the first gap GP1. A difference between the first gap GP1 and the second gap GP2 may be defined as a sliding gap.

To allow the first folding set FST1 to move toward the central portion of the folding set FST by the sliding gap when compared to the second folding set FST2, the second biaxial rotational axes RX1′ and RX2′ may be disposed below the first biaxial rotational axes RX1 and RX2.

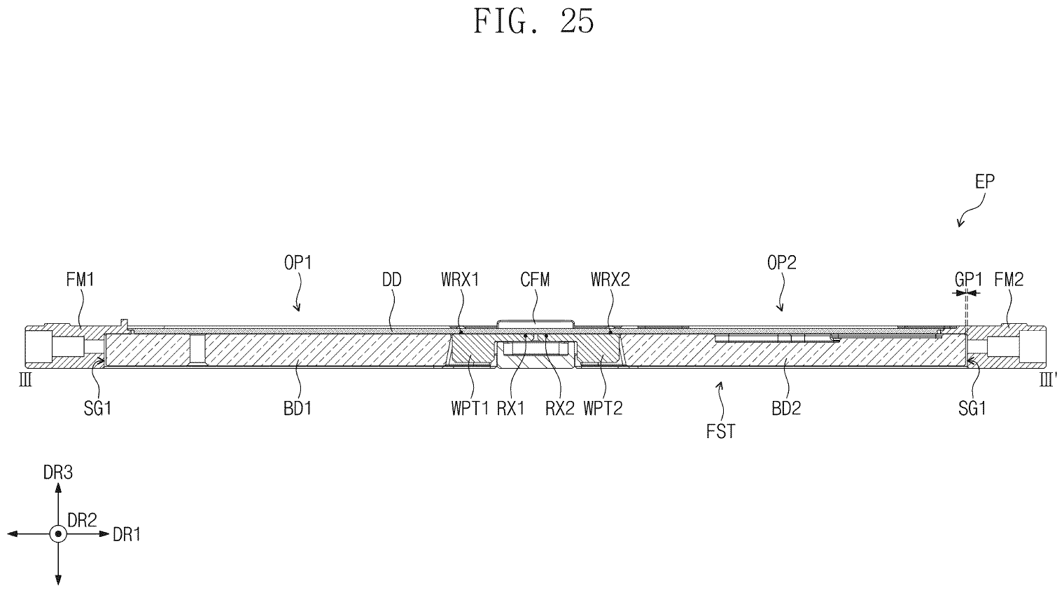

FIG. 25 is a sectional view taken along the line III-III′ in FIG. 10. FIG. 26 is a view illustrating the folding set and the display device illustrated in FIG. 25 in a folded state.

Referring to FIGS. 25 and 26, the display device DD may be folded as the folding set FST is folded by rotating about the first biaxial rotational axes RX1 and RX2. The display device DD may be disposed on the first body BD1 and the second body BD2 exposed by the first opening OP1 and the second opening OP2. In addition, the periphery of the display device DD may be disposed on the inner surfaces of the first frame FM1 and the second frame FM2 that define the first opening OP1 and the second opening OP2.

When the folding set FST is folded, the first wing plate WPT1 and the second wing plate WPT2 may also rotate about the first wing rotational axis WRX1 and the second wing rotational axis WRX2. First sides of the first wing plate WPT1 and the second wing plate WPT2 that face each other when the folding set FST is unfolded may move away from each other when the folding set FST is folded.

When the folding set FST is folded, the display device DD may be folded in a dumbbell shape. When the display device DD is folded in a dumbbell shape, the above-described first extension EX1 may be disposed on the first wing plate WPT1 and the above-described second extension EX2 may be disposed on the second wing plate WPT2. The first wing plate WPT1 may support the first extension EX1, and the second wing plate WPT2 may support the second extension EX2.

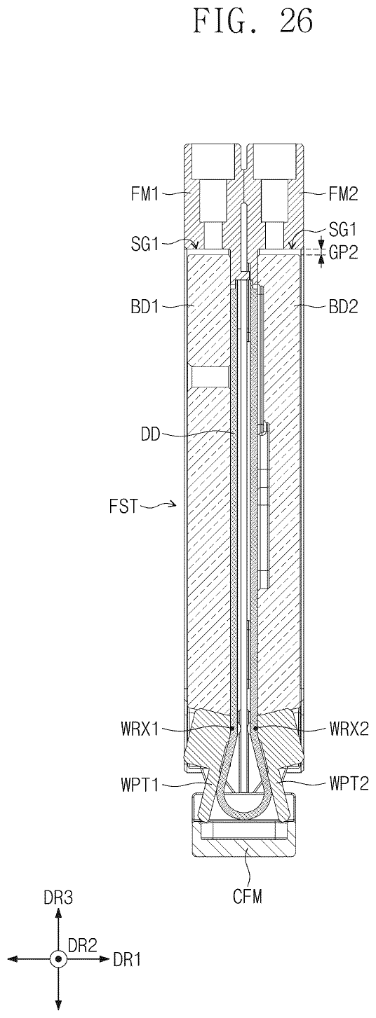

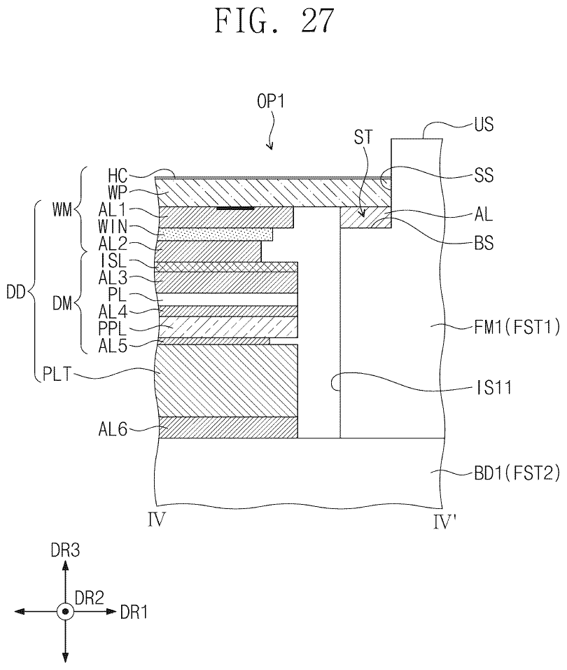

FIG. 27 is a sectional view taken along the line IV-IV′ in FIG. 10.

In FIG. 27, the lower portion of the first body BD1 and the components below the first body BD1 are omitted for convenience of description.

Referring to FIG. 27, an upper portion of an inner surface IS11 of the first frame FM1 that defines the first opening OP1 may have a step portion ST having a stepped shape. Although not illustrated in the sectional view, an upper side of an inner surface of the second frame FM2 that defines the second opening OP2 may also have a step portion having a stepped shape. The step portion ST may have a flat bottom surface BS and a side surface SS extending upwardly from an end of the bottom surface BS that faces toward the inside of the first frame FM1 (or the inside of the second frame FM2).

As described above, the display device DD may be disposed on the first body BD1 and the second body BD2 exposed by the first opening OP1 and the second opening OP2. In addition, the display device DD may be disposed on the step portion ST.

The display device DD may be attached to the upper surface of the first body BD1 and the bottom surface BS of the step portion ST of the first frame FM1. Similarly, the display device DD may also be attached to the upper surface of the second body DB2 and the bottom surface of the step portion of the second frame FM2.

The support plate PLT may be disposed on the first body BD1 and the second body BD2. The periphery of the window protection layer WP may extend outwardly further than (e.g., may extend beyond) the electronic panel EP, the window WIN, and the support plate PLT and may be disposed on the step portion ST. The periphery of the window protection layer WP may be disposed on the bottom surface BS. The periphery of the window protection layer WP may be disposed to contact the side surface SS of the step portion ST.

An adhesive layer AL may be disposed between the portion of the window protection layer WP that overlaps the bottom surface BS and the bottoms surface BS. A sixth adhesive layer AL6 may be disposed between the support plate PLT and the first body BD1. The portion of the window protection layer WP that overlaps the bottom surface BS and the bottom surface BS may be bonded to each other by the adhesive layer AL. The support plate PLT and the first body BD1 may be bonded to each other by the sixth adhesive layer AL6.

Similarly, the window protection layer WP may be attached to the bottom surface of the step portion of the second frame FM2 by the adhesive layer AL. In addition, the support plate PLT may be attached to the second body BD2 by the sixth adhesive layer AL6.

According to the above-described structure, the display device DD may be more firmly attached and fixed to the first frame FM1, the second frame FM2, the first body BD1, and the second body BD2.

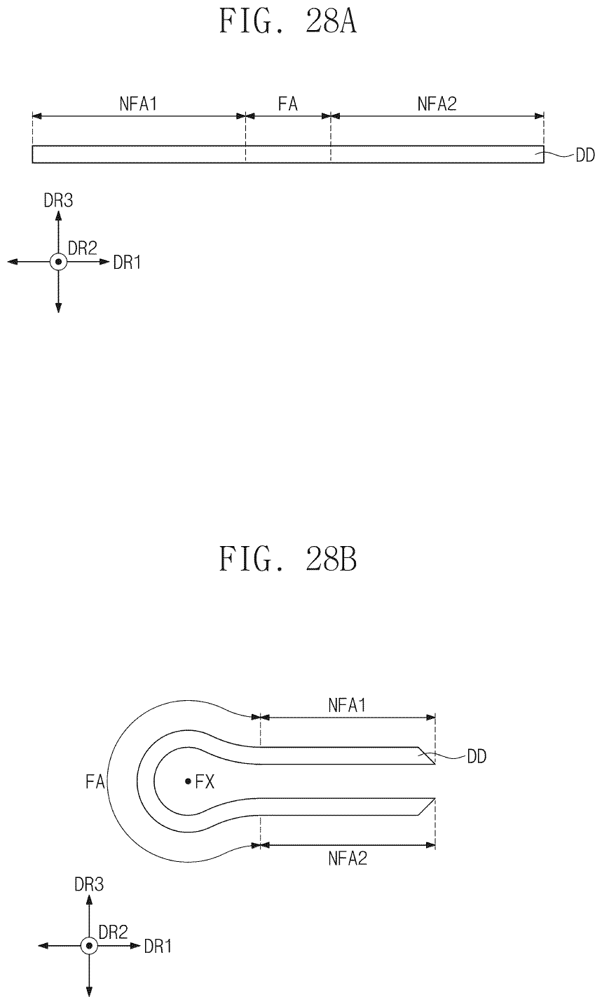

FIG. 28A is a side view of the display device when the display device illustrated in FIG. 1 is viewed in the second direction. FIG. 28B is a view illustrating the display device illustrated in FIG. 28A in a folded state.

Referring to FIGS. 28A and 28B, the upper side of the display device DD may protrude farther outwardly when the display device DD is folded than when the display device DD is unfolded. This deformation may occur depending on deformation of adhesive layers having fluidity.

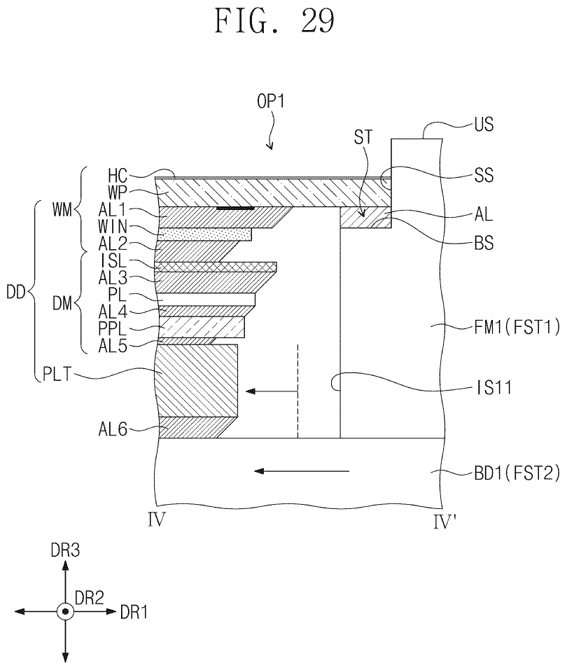

FIG. 29 is a view illustrating a deformed state of the display device when the display device illustrated in FIG. 27 is folded.

Referring to FIGS. 25, 26, 27, 28A, 28B, and 29, when the folding set FST is folded so that the display device DD is folded, the first to sixth adhesive layers AL1 to AL6 having fluidity may slip.

The first body BD1 and the second body BD2 may move toward the central portion of the folding set FST when compared to the sliding units SU, the first frame FM1, and the second frame FM2. Accordingly, the first to sixth adhesive layers AL1 to AL6 may slip toward the central portion of the folding set FST. In addition, the window WIN, the impact absorbing layer ISL, the electronic panel EP, the panel protection layer PPL, and the support plate PLT, which are disposed under the window protection layer WP, may slip toward the central portion of the folding set FST.

When the folding set FST is unfolded so that the display device DD is unfolded, the first to sixth adhesive layers AL1 to AL6 may slip to return to the correct (or original) positions. In addition, when the display device DD is unfolded, the window WIN, the impact absorbing layer ISL, the electronic panel EP, the panel protection layer PPL, and the support plate PLT may slip to return to the correct (or original) positions.

As described above, the window protection layer WP, which is an upper structure of the display device DD, may be attached and fixed to the first frame FM1 and the second frame FM2, and the support plate PLT may be attached and fixed to the first body BD1 and the second body BD2. Accordingly, the display device DD may be more firmly fixed to the folding set FST.

Because the window protection layer WP, which is an upper structure of the display device DD, is attached and fixed to the step portion ST, the position of the window protection layer WP may be fixed. In such an embodiment, the positions of the window module WM and the display module DM may also remain more constant.

In the fixed state described above, the degree of freedom of the display device DD may be low. The degree of freedom may be defined as the extent to which the display device DD moves in various directions. When the display device DD is folded and unfolded in the fixed state in which the degree of freedom is low, the amount of expansion and contraction of the first to sixth adhesive layers AL1 to AL6 may be more constant.

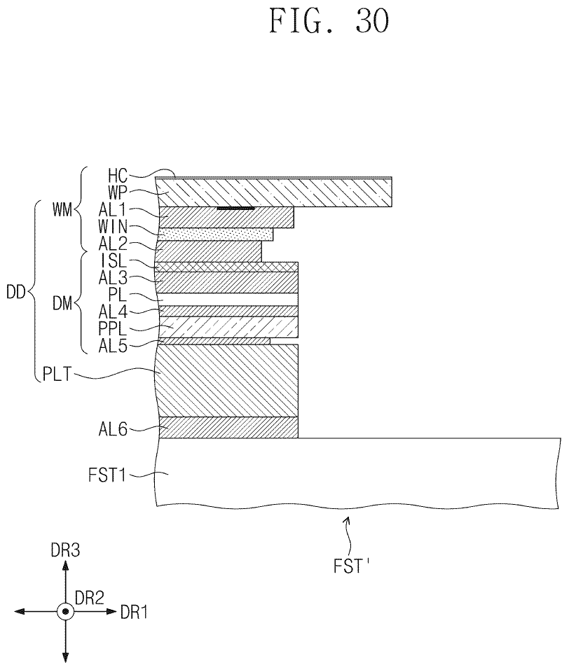

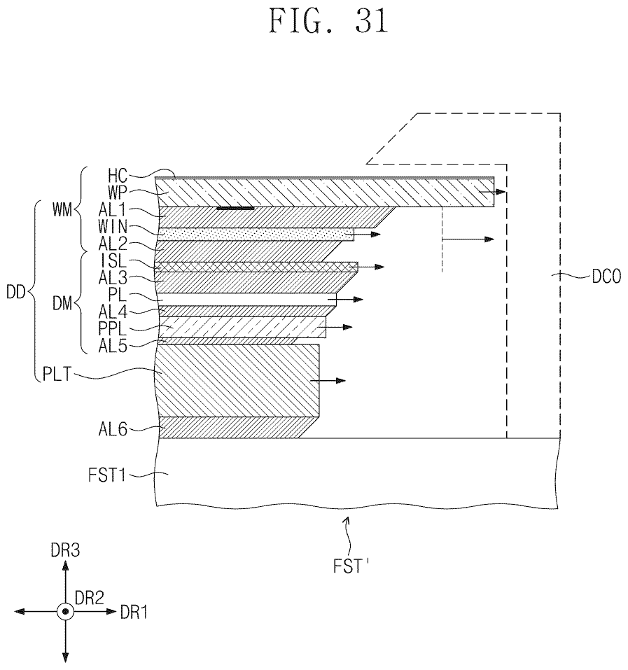

FIG. 30 is a view illustrating a configuration of a folding set according to a comparative example. FIG. 31 is a view illustrating a deformed state of the display device when the comparative folding set illustrated in FIG. 30 is folded.

Referring to FIG. 30, the comparative folding set FST′ may not include the first folding set FST1 and may include only the second folding set FST2. Only the first body BD1 and the second body BD2 may be disposed under the display device DD, and accordingly the support plate PLT may be attached and fixed to the first body BD1 and the second body BD2.

The display module DM and the window module WM disposed on the support plate PLT may not be fixed to the comparative folding set FST′. Accordingly, the degree of freedom of the display module DM and the window module WM on the support plate PLT may be higher than that when the second folding set FST2 is used.

When the display device DD is folded and unfolded as the comparative folding set FST′ is folded and unfolded, the first to sixth adhesive layers AL1 to AL6 may slip. When the degree of freedom is high, the window protection layer WP, the window WIN, the electronic panel EP, the impact absorbing layer ISL, and the panel protection layer PPL may move in various directions depending on the slip of the first to sixth adhesive layers AL1 to AL6. In addition, the amount of expansion and contraction of the first to sixth adhesive layers AL1 to AL6 may be diversely varied. In this case, the display device DD may be more rapidly deformed.

In addition, as illustrated in FIG. 31, when the display device DD is folded, the window protection layer WP, the window WIN, the electronic panel EP, the impact absorbing layer ISL, and the panel protection layer PPL, which are disposed on the support plate PLT, may slip outwardly depending on the deformation of the first to sixth adhesive layers AL1 to AL6. In this case, a separate deco layer DCO (illustrated by a dotted line) may be required to hide the window protection layer WP, the window WIN, the electronic panel EP, the impact absorbing layer ISL, and the panel protection layer PPL that slip outwardly.

In an embodiment of the present disclosure, because the support plate PLT and the window protection layer WP are fixed to the first folding set FST1 and the second folding set FST2, the degree of freedom of the display device DD may be lowered. Accordingly, the positions of the window module WM and the display module DM may remain more constant, and the amount of expansion and contraction of the first to sixth adhesive layers AL1 to AL6 may be more constant. Thus, deformation of the display device DD may be reduced.

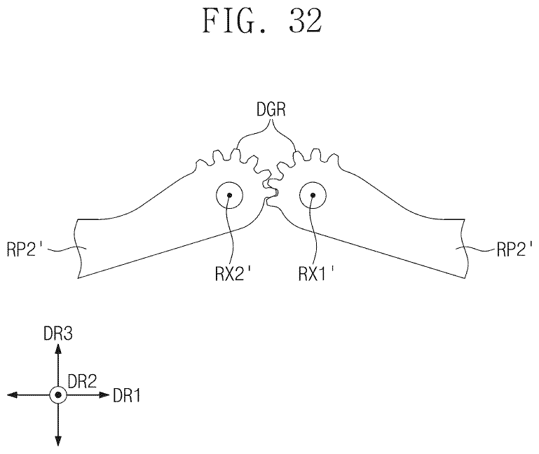

FIG. 32 is a view illustrating a configuration of second rotating parts according to an embodiment of the present disclosure.

Referring to FIG. 32, different from the second rotating parts RP2 illustrated in FIG. 19, first sides of the second rotating parts RP2′ facing each other in the first direction DR1 may include dummy gears DGR and may be disposed to be engaged with each other.

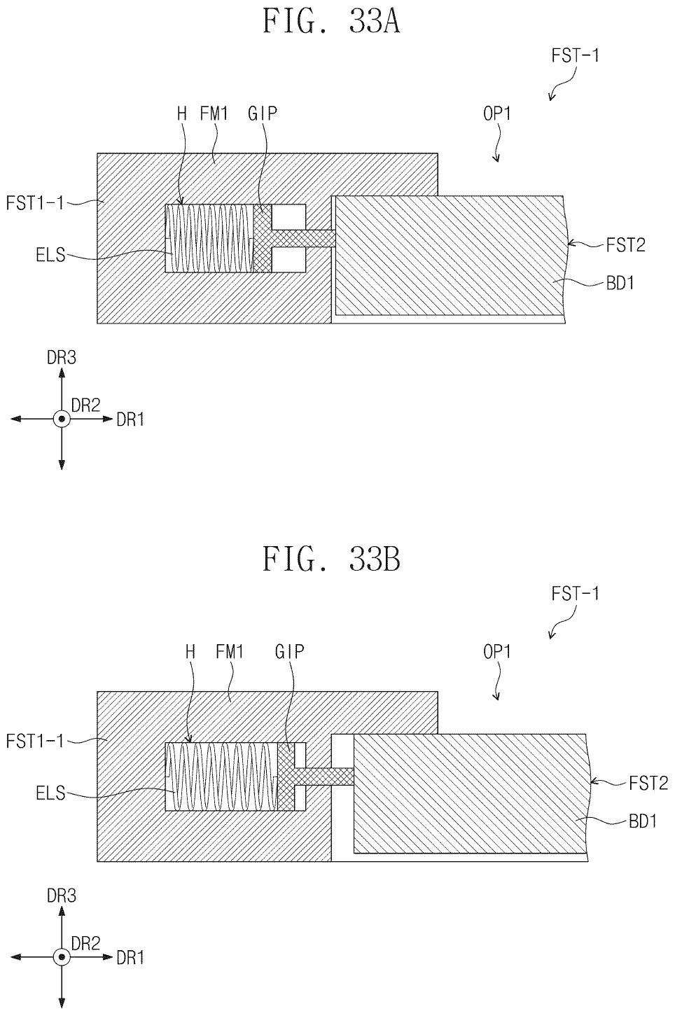

FIGS. 33A and 33B are views illustrating a configuration of a folding set according to an embodiment of the present disclosure.

FIG. 33A may represent the folding set FST-1 in an unfolded state, and FIG. 33B may represent the folding set FST-1 in a folded state.

Referring to FIG. 33A, a first folding set FST1-1 of the folding set FST-1 may include an elastic part ELS and a guide part GIP that are disposed in a first frame FM1. A hole (e.g., an opening) H open toward a first body BD1 in the first direction DR1 may be defined in the first frame FM1.

The elastic part ELS and the guide part GIP may be disposed in the hole H. The guide part GIP may be disposed between the elastic part ELS and the first body BD1 and may contact the first body BD1. The elastic force of the elastic part ELS may be applied to the first body BD1 through the guide part GIP.

An elastic part ELS and a guide part GIP may be disposed in a second frame FM2, and the guide part GIP may be disposed between the elastic part ELS and a second body BD2 and may contact the second body BD2.

Referring to FIGS. 33A and 33B, the elastic force of the elastic part ELS may be applied to the first body BD1 through the guide part GIP and, thus, in folding and unfolding operations, a moved state of the first body BD1 may be more firmly fixed.

According to embodiments of the present disclosure, the display device may be disposed on the upper surface of the second folding set exposed through the openings of the first folding set and may be fixedly disposed on the step portions of the inner surfaces of the first folding set that define the openings. Accordingly, the display device may be folded and unfolded while being more firmly fixed to the folding set, and thus, deformation of the display device may be reduced.

Although the present disclosure has been described in connection with embodiments thereof, it will be understood by those skilled in the art that various changes in form and details may be made therein without departing from the spirit and scope of the present disclosure as set forth in the following claims and their equivalents. In addition, the embodiments disclosed herein are not intended to limit the technical spirit of the present disclosure, and all technical concepts falling within the scope of the following claims and equivalents thereof are to be construed as being included in the scope of the present disclosure.

What is claimed is:

1. A folding set comprising:
a first folding set comprising a first frame, a second frame, and a hinge between the first frame and the second frame; and
a second folding set comprising a first body under the first frame and a second body under the second frame,
wherein the first frame and the hinge are coupled with each other to define a first frame shape having a first opening defined therein, and the second frame and the hinge are coupled with each other to define a second frame shape having a second opening defined therein, and
wherein the first body is exposed by the first opening, and the second body is exposed by the second opening.

2. The folding set of claim 1, wherein each of an upper portion of an inner surface of the first frame that defines the first opening and an upper portion of an inner surface of the second frame that defines the second opening has a step portion having a stepped shape.

3. The folding set of claim 2, further comprising a display device on the first body, the second body, and the step portion.

4. The folding set of claim 3, wherein the step portion has:
a flat bottom surface; and
a side surface extending upwardly from an end of the bottom surface and facing toward an inside of the first frame and the second frame, and
wherein the display device is attached to upper surfaces of the first body and the second body and the bottom surface.

5. The folding set of claim 4, wherein the display device comprises:
an electronic panel;
a window on the electronic panel;
a window protection layer on the window; and
a support plate under the electronic panel and on the first body and the second body, and
wherein a periphery of the window protection layer extends outwardly with respect to the electronic panel, the window, and the support plate and is on the step portion.

6. The folding set of claim 5, wherein the periphery of the window protection layer contacts the side surface of the step portion.

7. The folding set of claim 1, wherein the first frame and the second frame are spaced apart from each other in a first direction, and
wherein the hinge defines first biaxial rotational axes extending parallel to each other in a second direction crossing the first direction.

8. The folding set of claim 7, wherein the hinge comprises:
a central frame extending in the second direction; and
a plurality of first rotating parts rotatably coupled to first portions of the central frame to define the first biaxial rotational axes, the first portions of the central frame being adjacent to opposite sides of the central frame opposite to each other in the second direction,
wherein the first rotating parts extend in the first direction and are connected to the first frame and the second frame, and
wherein first sides of the first rotating parts facing each other in the first direction comprise gears and are configured to be engaged with each other.

9. The folding set of claim 8, wherein the second folding set further comprises:
a first wing plate rotatably coupled to a first side of the first body and facing the second body;
a second wing plate rotatably coupled to a first side of the second body and facing the first body; and
a plurality of second rotating parts adjacent to opposite sides of the first body and the second body and connected to the first sides of the first body and the second body, the opposite sides of the first body and the second body being opposite to each other in the second direction, and
wherein the first wing plate and the second wing plate are between the second rotating parts in the second direction.

10. The folding set of claim 9, wherein the first wing plate and the second wing plate are on the central frame,
wherein the second rotating parts are rotatably coupled to second portions of the central frame arranged inwardly of the first portions to define second biaxial rotational axes, and
wherein the first biaxial rotational axes are spaced apart from the second biaxial rotational axes.

11. The folding set of claim 10, wherein the second biaxial rotational axes are defined below the first biaxial rotational axes.

12. The folding set of claim 10, wherein first sides of the second rotating parts facing each other in the first direction comprise dummy gears and are configured to be engaged with each other.

13. The folding set of claim 1, wherein the first folding set and the second folding set are coupled to slide relative to each other.

14. The folding set of claim 13, further comprising a plurality of sliding units under the first body and the second body,
wherein the sliding units are connected to the first frame and the second frame through sliding openings defined in the first body and the second body.

15. The folding set of claim 14, wherein the first frame and the second frame comprise a plurality of protrusions protruding toward the sliding units, and
wherein the protrusions are connected to the sliding units.

16. The folding set of claim 15, wherein the protrusions are configured to move along the sliding openings when the first folding set is folded by the hinge.

17. The folding set of claim 14, wherein, when viewed from on a plane, each of the sliding units has a larger area than each of the sliding openings.

18. The folding set of claim 1, further comprising:
an elastic part in each of the first frame and the second frame; and
a guide part between each of the first body and the second body and the elastic part.

19. A folding set comprising:
a first folding set comprising a first frame, a second frame, and a hinge between the first frame and the second frame; and
a second folding set comprising a first body under the first frame and a second body under the second frame,
wherein the first frame and the hinge are coupled with each other to define a first frame shape having a first opening defined therein, and the second frame and the hinge are coupled with each other to define a second frame shape having a second opening defined therein, and
wherein each of an upper portion of an inner surface of the first frame defining the first opening and an upper portion of an inner surface of the second frame defining the second opening has a step portion having a stepped shape.

20. An electronic device comprising:
a first folding set comprising a first frame, a second frame, and a hinge between the first frame and the second frame, the first folding set having openings defined between the hinge, the first frame, and the second frame;
a second folding set comprising a first body under the first frame and a second body under the second frame; and
a display device on the second folding set through the openings,
wherein each of an upper portion of an inner surface of the first frame and an upper portion of an inner surface of the second frame defining the openings has a step portion having a stepped shape, and
wherein the display device is on the first body, the second body, and the step portion.
